(19) United States
(12) Patent Application Publication
(10) Pub. No.: US 2005/0051806 A1
(43) Pub. Date: Mar. 10, 2005

(54) Memory cell unit, nonvolatile semiconductor device, and liquid crystal display device including the nonvolatile semiconductor device

(75) Inventors: Fujio Masuoka, Sendai-shi (JP); Hiroshi Sakuraba, Sendai-shi (JP); Fumiyoshi Matsuoka, Sendai-shi (JP); Syounosuke Ueno, Fujiidera-shi (JP)

Correspondence Address: MORRISON & FOERSTER LLP, 755 PAGE MILL RD, PALO ALTO, CA, 94304-1018, US

(73) Assignees: FUJIO MASUOKA, Sendai-shi (JP); SHARP KABUSHIKI KAISHA, Osaka-shi (JP)

(21) Appl. No.: 10/930,229

(22) Filed: Aug. 30, 2004

(30) Foreign Application Priority Data
Sep. 8, 2003 (JP) 2003-315492

(51) Int. Cl. H01L 29/768

(52) U.S. Cl. 257/222

(57) ABSTRACT

A memory cell unit including: a semiconductor substrate having a source diffusion layer provided in a surface thereof; a column-shaped semiconductor layer provided on the source diffusion layer and having a drain diffusion layer provided in an uppermost portion thereof; a memory cell arrangement which includes a plurality of memory cells arranged in series with the intervention of a first impurity diffusion layer; a first selection transistor connected to one end of the memory cell arrangement with the intervention of a second impurity diffusion layer and connected to the drain diffusion layer; and a second selection transistor connected to the other end of the memory cell arrangement with the intervention of a third impurity diffusion layer and connected to the source diffusion layer; wherein a distance between the third impurity diffusion layer and the source diffusion layer is greater than a distance between impurity diffusion layers disposed on opposite sides of each of the memory cells, whereby punch-through of the second selection transistor is prevented when a writing prevention voltage is applied between the source diffusion layer and the first impurity diffusion layer.

### CROSS-REFERENCE TO RELATED APPLICATION

This application is related to Japanese application No.2003-315492 filed on Sep. 8, 2003 whose priority is claimed under 35 USC §119, the disclosure of which is incorporated by reference in its entirety.

### BACKGROUND OF THE INVENTION

1. Field of the Invention

The present invention relates to a memory cell unit, a nonvolatile semiconductor storage device and a liquid crystal display device including the nonvolatile semiconductor storage device.

2. Description of the Related Art

Exemplary memory cells of a known EEPROM are of a MOS transistor structure, which includes a gate portion including a charge storage layer and a control gate and is adapted to inject electric charges into the charge storage layer and release the electric charges from the charge storage layer by utilizing a tunnel current. The memory cells each store data “0” and “1” on the basis of a difference in threshold voltage attributable to a difference in the charge storage state of the charge storage layer.

In the case of an n-channel memory cell having a floating gate as the charge storage layer, for example, a positive high voltage is applied to the control gate with source and drain diffusion layers and a substrate being grounded for the injection of electrons into the floating gate. At this time, the electrons are injected into the floating gate from the substrate by the tunnel current. Thus, the threshold voltage of the memory cell is positively shifted by the injection of the electrons. For the release of the electrons from the floating gate, on the other hand, a negative voltage is applied to the control gate with the source and drain diffusion layers and the substrate being grounded. At this time, the electrons are released from the floating gate to the substrate by the tunnel current. Thus, the threshold voltage of the memory cell is negatively shifted by the release of the electrons. In the aforesaid operation, a relationship between a floating gate/control gate coupling capacitance and a floating gate/substrate coupling capacitance is important for efficiently achieving the electron injection and the electron release, i.e., for the writing and the erasing. In other words, as the capacitance between the floating gate and the control gate is increased, the potential of the control gate can more effectively be transferred to the floating gate, thereby facilitating the writing and the erasing.

With the recent progress of the semiconductor technology, particularly the micro-processing technique, the size reduction and capacity increase of the memory cells of EEPROMs are rapidly promoted. Therefore, how to reduce the area of the memory cells and how to increase the capacitance between the floating gate and the control gate are critical issues. In order to increase the capacitance between the floating gate and the control gate, it is necessary to reduce the thickness of a gate insulation film provided between the floating gate and the control gate, to increase the dielectric constant of the gate insulation film, or to increase the area of opposed surfaces of the floating gate and the control gate. However, the thickness reduction of the gate insulation film has limitation in consideration of the reliability. A conceivable approach to the increase of the dielectric constant of the gate insulation film is to employ a silicon nitride film or the like instead of a silicon oxide film. However, this approach poses a problem associated with the reliability and, hence, is not practical. Therefore, it is necessary to increase an overlap between the floating gate and the control gate to not smaller than a predetermined area in order to provide a sufficient capacitance. However, this is obstructive to the reduction of the area of the memory cells for the increase of the storage capacity of the EEPROM. Hence, there is a demand for means for achieving the reduction of the memory cell area and the increase of the capacitance between the floating gate and the control gate.

On the other hand, an EEPROM as shown in FIG. 40 is known (see, for example, Japanese Unexamined Patent Publication No. Hei 4-79369 (1992)), which includes a plurality of memory cell units (memory transistors) each including two memory cells provided on a column-shaped semiconductor layer 12 and selection transistors disposed above and below the memory cells. The memory transistors are constructed by utilizing peripheral walls of plural column-shaped semiconductor layers 12 arranged in a matrix configuration and isolated from each other by a lattice trench formed in a semiconductor substrate. That is, the memory transistors are each constituted by a drain diffusion layer 7 provided in an upper surface of each of the column-shaped semiconductor layers, a common source diffusion layer 11 provided in a bottom of the trench, and charge storage layers 1, 3 and control gates 2, 4 entirely surrounding the peripheral surface of the column-shaped semiconductor layer. Control gate lines are each provided by sequentially connecting control gates provided around column-shaped semiconductor layers serially arranged in one direction. Bit lines are each connected to drain diffusion layers of memory transistors arranged as crossing the control gate lines. Where the memory cells each have a one-transistor-per-cell structure, a cell current flows into unselected cells (or a reading error occurs) if the memory transistors are over-erased with a read potential of 0V and a negative threshold voltage. To assuredly prevent this phenomenon, the selection gate transistors are disposed in series to the memory cells in upper and lower portions of the column-shaped semiconductor layer with gate electrodes 5, 6 thereof at least partly surrounding the peripheral surface of the column-shaped semiconductor layer.

Thus, the memory cells of the conventional EEPROM each include the charge storage layer and the control gate formed as surrounding the column-shaped semiconductor layer by utilizing the peripheral wall of the column-shaped semiconductor layer. Therefore, the capacitance between the charge storage layer and the control gate can sufficiently be increased with a smaller memory cell area. Further, the drain diffusion layers connected to the bit lines are respectively provided in the upper surfaces of the column-shaped semiconductor layers, and electrically isolated from each other by the trench. Thus, a device isolation area can be reduced, thereby further reducing the memory cell size. Therefore, it is possible to provide a large storage capacity EEPROM in which memory cells each having an excellent writing/erasing efficiency are integrated.

It is herein assumed that memory cells connected in series on each of the column-shaped semiconductor layers have the same threshold voltage. Here, a reading operation is performed by applying a read potential to control gate lines (CG) of the memory cells for determination of “0” or “1” depending on the presence or absence of the electric current. If the electric current flowing through the semiconductor layer causes a potential difference between the memory cells located at opposite ends of the serial memory cell arrangement on the single semiconductor layer due to a resistant component of the semiconductor layer, the potential difference makes the threshold voltages of the respective memory cells non-uniform (back bias effect). This enhances fluctuation in the threshold voltage. The back bias effect limits the number of memory cells to be connected in series on the device, thereby posing a problem associated with the increase of the storage capacity. Further, the back bias effect may occur not only where the plural memory cells are connected in series on the single column-shaped semiconductor layer, but also where a single memory cell is provided on the single column-shaped semiconductor layer. That is, the threshold voltages of the respective memory cells are liable to be non-uniform due to variation in an in-plane back bias effect of the semiconductor substrate. The variations in the threshold voltages depending on the positions of the memory cells adversely influence write/erase/read voltages to be applied for the writing, erasing and reading operations with respect to the memory cells. Hence, there is a demand for a solution to the problem associated with the back bias effect of the substrate.

On the other hand, there is also known an EEPROM in which column-shaped semiconductor layers are electrically isolated from a semiconductor substrate as shown in FIG. 41 (see, for example, Japanese Unexamined Patent Publication No. 2002-57231). By thus electrically isolating the column-shaped semiconductor layers from the semiconductor substrate, the back bias effect can be suppressed. Therefore, an EEPROM having an improved integration density can be provided, in which the coupling ratio of the floating gate/control gate coupling capacitance is further increased without increasing the area of the memory cells, and the variations in cell characteristics attributable to the production process are suppressed.

In either of the EEPROMs described in the aforesaid patent publications, a positive high voltage is applied to a control gate of a memory cell to be subjected to a writing operation. At this time, a bit line writing prevention voltage is applied to bit lines connected to memory cells which share the control gate line with the control gate of the memory cell applied with the positive high voltage and are not subjected to charge storage layer electron injection. However, the aforesaid patent publications teach nothing about breakdown voltages of the selection transistors with respect to the bit line writing prevention voltage.

An equivalent circuit for the conventional EEPROMs is shown in FIG. 42. A nonvolatile semiconductor storage device including a plurality of memory cells and two selection transistors provided on opposite sides of the memory cells as shown in FIG. 42 is generally referred to as “NAND memory cell unit”. An exemplary memory cell unit array including a plurality of such NAND memory cell units arranged in a matrix configuration is shown in FIG. 43, and an equivalent circuit diagram of the memory cell unit array is shown in FIG. 44. In FIG. 44, there are also shown voltages to be applied to respective terminals where a writing operation is performed on a lower memory cell of a NAND memory cell unit Paa but not performed on a lower memory cell of a memory cell unit Pab with a control gate line CG1a being selected. In this case, a positive high voltage VH1 is applied to the control gate line CG1a, and a bit line writing prevention voltage VH4 is applied to a bit line BLb of the memory cell unit Pab having the unselected cell. FIG. 45 is a graph illustrating changes in channel potentials Vch1, Vch2 of the lower and upper memory cells observed with time when the writing prevention voltage is applied to the bit line BLb. With the application of the writing prevention voltage VH4, the channel potential Vch1 of the unselected cell is increased. If the source-drain voltage of the selection transistor adjacent to a source diffusion layer is increased to higher than the breakdown voltage VB1 of the selection transistor, breakdown occurs. As a result, the channel potential Vch1 of the unselected cell is reduced until the source-drain voltage (i.e., a difference between the channel potential Vch1 and the grounding potential of the source diffusion layer) is equalized to the breakdown voltage VB1. Here, the voltage application to the bit line BLb follows the voltage application to the selection gate line SG2a and the control gate lines CG1a, CG2a. However, the channel potential Vch1 is reduced to the breakdown voltage VB1 whether the voltage application to the bit line BLb follows or precedes the voltage application to the selection gate line SG2a and the control gate lines CG1a, CG2a. The channel potential Vch1 should be not lower than the bit line writing prevention voltage VH4 for the prevention of the writing. However, a voltage between the control gate line CG1 and a floating channel is equivalent to a difference between the high voltage VH1 and the breakdown voltage VB1. Hence, there is a possibility that a writing error occurs if the breakdown voltage VB1 is lower than the voltage VH4.

On the other hand, where the writing operation is performed on an upper memory cell of the NAND memory cell unit Paa but not performed on an upper memory cell of the NAND memory cell unit Pab with the control gate line CG2a being selected, the positive high voltage VH1 is applied to the control gate line CG2a, and the bit line writing prevention voltage VH4 is applied to the bit line BLb of the memory cell unit Pab having the unselected cell. When the writing prevention voltage is applied to the bit line BLb, the channel potentials Vch1, Vch2 of the lower and upper memory cells change with time in the same manner as in FIG. 45, and are reduced to the breakdown voltage VB1. Here, the voltage application to the bit line follows the voltage application to the selection gate line SG2a and the control gate lines CG1a, CG2a. However, the channel potential Vch2 is reduced to the breakdown voltage VB1 whether the voltage application to the bit line follows or precedes the voltage application to the selection gate line SG2a and the control gate lines CG1a, CG2a. The channel potential Vch2 should be not lower than the bit line writing prevention voltage VH4 for the prevention of the writing. However, a voltage between the control gate line CG2 and a floating channel is equivalent to a difference between the high voltage VH1 and the breakdown voltage VB1. Hence, there is a possibility that a writing error occurs if the breakdown voltage VB1 is lower than the writing prevention voltage VH4.

FIG. 46 is a block diagram of a memory cell unit array including NAND memory cells arranged in a matrix configuration and sharing plural control gate lines. FIG. 47 is an equivalent circuit of the memory cell unit array. In FIG. 47, there are also shown voltages to be applied to respective terminals where a writing operation is performed on a lower memory cell of a memory cell unit Paa but not performed on a lower memory cell of a memory cell unit Pab with a common control gate line CG1a being selected.

In the memory cell unit array shown in FIG. 43, one control gate selector transistor should be provided for each row of memory cell units arranged along a control gate line in a space having a width as measured along a bit line (vertically in FIG. 43) for the row of memory cell units (i.e., one control gate selector transistor is required for each control gate line). On the other hand, the memory cell unit array shown in FIG. 46 is advantageous in that an interconnection routing pitch of control gate lines is increased by connecting each two control gate lines to one common line, and one control gate selector transistor is disposed in a space having a width as measured along a bit line for two rows of memory cell units (in this case, one control gate selector transistor is required for each two control gate lines). However, a positive high voltage VH1 is applied to control gates of lower memory cells of memory cell units Pba, Pbb to Pbc, Pbd whose selection gate lines SGb1, SGb2 are unselected, because the plural control gate lines are shared. FIG. 48 is a circuit diagram illustrating a simplified capacitance network of the memory cell unit Pba. Since the column-shaped semiconductor layers of the memory cell units are electrically isolated from the semiconductor substrate in the EEPROM, the channel potential Vch1 of the lower memory cell is determined by a coupling relationship of a capacitance Ci_poly between the floating gate and the control gate, a capacitance Cox between the floating gate and the channel layer, and capacitances C1, C2, C3 of depletion layers formed in junctions between the channel layers and impurity layers each having a conductivity opposite to the conductivity of the channel layers. FIG. 49 is a graph illustrating a change in the channel potential Vch1 of an unselected memory cell when the positive high voltage VH1 is applied to the control gate line CG1a. With the application of the positive high voltage VH1 to the control gate line CG1a, the channel potential Vch1 of the unselected cell is initially increased by the coupling of the capacitance Ci_poly between the floating gate and the control gate and the capacitance Cox between the floating gate and the channel layer. If the source-drain voltage of the selection transistor adjacent to the source line is increased to higher than the source-drain breakdown voltage VB1, breakdown occurs. As a result, the channel potential Vch1 is reduced until the source-drain voltage is equalized to the breakdown voltage VB1. Here, an explanation has been given to the case where the bit line of the lower memory cell of the memory cell unit Pba is at a grounding potential. Where a writing prevention voltage VH4 is applied to bit lines, the channel potentials Vch1 of the lower memory cells of the memory cell units Pba, Pbb to Pbc, Pbd are also reduced to the breakdown voltage VB1. The channel potentials Vch1 should be not lower than the bit line writing prevention voltage VH4 for the prevention of the writing. However, voltages between the control gate line CG1a and floating channels are equivalent to a difference between the high voltage VH1 and the breakdown voltage VB1. Hence, there is a possibility that a writing error occurs if the breakdown voltage VB1 is lower than the writing prevention voltage VH4.

On the other hand, where the writing operation is performed on an upper memory cell of a NAND memory cell unit Paa but not performed on an upper memory cell of a NAND memory cell unit Pab with a control gate line CG2a being selected, a positive high voltage VH1 is applied to the control gate line CG2a, and a voltage VH2 (VH2<VH1) such as to prevent the writing is applied to the control gate line CG1a. Further, a bit line BLa of the memory cell array Paa having the selected cell is kept at a grounding potential, and a bit line writing prevention voltage VH4 is applied to a bit line BLb of the memory cell unit Pab having the unselected cell. Selection gate lines SG1b, SG2b of the memory cell units Pba, Pbb to Pbc, Pbd connected to the control gate line CG2a are kept at the grounding potential. Since the plural control gate lines are shared, the positive high voltage VH1 is also applied to the control gates of the upper memory cells of the unselected memory cell units Pba, Pbb to Pbc, Pbd with the selection gate lines SGb1, SGb2 kept at the grounding potential. FIG. 50 is a circuit diagram illustrating a simplified capacitance network of the column-shaped semiconductor layer Pba. The channel potential Vch2 of the upper memory cell is determined by a coupling relationship of a capacitance Ci_poly between the floating gate and the control gate, a capacitance Cox between the floating gate and the channel layer, and capacitances C1, C2, C3 of depletion layers formed in junctions between the channel layers and impurity layers each having a conductivity opposite to the conductivity of the channel layers. FIG. 51 illustrates a change in the channel potential Vch2 of the memory cell observed when the positive high voltage VH1 is applied to the control gate line CG2a. With the application of the positive high voltage VH1 to the control gate line CG2a, the channel potential Vch2 is initially increased by the coupling of the capacitance Ci_poly between the floating gate and the control gate and the capacitance Cox between the floating gate and the channel layer. If the source-drain voltage of the selection transistor adjacent to the source line is increased to higher than the source-drain breakdown voltage VB2, breakdown occurs. As a result, the channel potential Vch2 is reduced until the source-drain voltage is equalized to the breakdown voltage VB2. The channel potential Vch2 should be not lower than the bit line writing prevention voltage VH4 for the prevention of the writing. However, a voltage between the control gate line CG2a and a floating channel is equivalent to a difference between the high voltage VH1 and the breakdown voltage VB2. Hence, there is a possibility that a writing error occurs if the breakdown voltage VB2 is lower than the writing prevention voltage VH4.

### SUMMARY OF THE INVENTION

In view of the foregoing, the invention is directed to a memory cell unit in which a selection transistor connected to a source diffusion layer has an inter-diffusion layer breakdown voltage which is not lower than a level equivalent to a difference between a writing prevention voltage to be applied to a bit line and a voltage to be applied to a source diffusion layer.

According to a first aspect of the present invention, there is provided a memory cell unit, which comprises: a semiconductor substrate having a source diffusion layer provided in a surface thereof; a column-shaped semiconductor layer provided on the source diffusion layer as extending perpendicularly to the semiconductor substrate and having a drain diffusion layer provided in an uppermost portion thereof; a memory cell arrangement which includes a plurality of memory cells arranged in series with the intervention of a first impurity diffusion layer on the column-shaped semiconductor layer perpendicularly to the substrate, the memory cells each having a charge storage layer and a control gate; a first selection transistor connected to one end of the memory cell arrangement with the intervention of a second impurity diffusion layer and connected to the drain diffusion layer; and a second selection transistor connected to the other end of the memory cell arrangement with the intervention of a third impurity diffusion layer and connected to the source diffusion layer; wherein a distance between the third impurity diffusion layer and the source diffusion layer is greater than a distance between impurity diffusion layers disposed on opposite sides of each of the memory cells, whereby punch-through of the second selection transistor is prevented when a writing prevention voltage is applied between the source diffusion layer and the first impurity diffusion layer.

According to a second aspect of the present invention, there is provided a memory cell unit, which comprises: a semiconductor substrate having a source diffusion layer provided in a part of a surface thereof; a column-shaped semiconductor layer provided on the semiconductor substrate perpendicularly to the semiconductor substrate with a part of a bottom thereof being in contact with the source diffusion layer and with the other part of the bottom thereof being electrically connected to the semiconductor substrate, and having a drain diffusion layer provided in an uppermost portion thereof; a memory cell arrangement which includes a plurality of memory cells arranged in series with the intervention of a first impurity diffusion layer on the column-shaped semiconductor layer perpendicularly to the substrate, the memory cells each having a charge storage layer and a control gate; a first selection transistor connected to one end of the memory cell arrangement with the intervention of a second impurity diffusion layer and connected to the drain diffusion layer; and a second selection transistor connected to the other end of the memory cell arrangement with the intervention of a third impurity diffusion layer and connected to the source diffusion layer; wherein a distance between the third impurity diffusion layer and the source diffusion layer is greater than a distance between impurity diffusion layers disposed on opposite sides of each of the memory cells, whereby punch-through of the second selection transistor is prevented when a writing prevention voltage is applied between the source diffusion layer and the first impurity diffusion layer.

According to the first inventive aspect, the memory cell unit is electrically isolated from the semiconductor substrate, and the distance between the third impurity diffusion layer and the source diffusion layer is greater than a distance between the first impurity diffusion layer and an impurity diffusion layer disposed on a side of the memory cell opposite from the first impurity diffusion layer. Therefore, the punch-through of the second selection transistor can be prevented when the writing prevention voltage is applied between the source diffusion layer and the third impurity diffusion layer. Therefore, when a writing operation is performed on a memory cell adjacent to the third impurity diffusion layer, the channel potential of the other unselected memory cell can be kept at the writing prevention voltage. Hence, erroneous writing to the unselected memory cell can assuredly be prevented, so that the memory cell unit is highly reliable and stably operable.

Where a distance between the drain diffusion layer and the second impurity diffusion layer is greater than the distance between the impurity diffusion layers disposed on the opposite sides of each of the memory cells, punch-through of the first selection transistor can be prevented when the writing prevention voltage is applied between the drain diffusion layer and the second impurity diffusion layer. Therefore, when the writing operation is performed on a memory cell adjacent to the second impurity diffusion layer, the channel potential of the other unselected memory cell can be kept at the writing prevention voltage. Hence, erroneous writing to the unselected memory cell can assuredly be prevented, so that the memory cell unit is highly reliable and stably operable.

According to the second inventive aspect, the memory cell unit is electrically connected to the semiconductor substrate, and the distance between the third impurity diffusion layer and the source diffusion layer is greater than the distance between the impurity diffusion layers disposed on the opposite sides of each of the memory cells. Therefore, the punch-through of the second selection transistor can be prevented when the writing prevention voltage is applied between the source diffusion layer and the third impurity diffusion layer. Therefore, when a writing operation is performed on a memory cell adjacent to the third impurity diffusion layer, the channel potential of the other unselected memory cell can be kept at the writing prevention voltage. Hence, erroneous writing to the unselected memory cell can assuredly be prevented, so that the memory cell unit is highly reliable and stably operable.

Where a distance between the drain diffusion layer and the second impurity diffusion layer is greater than the distance between the impurity diffusion layers disposed on opposite sides of each of the memory cells, punch-through of the first selection transistor can be prevented when the writing prevention voltage is applied between the drain diffusion layer and the second impurity diffusion layer. Therefore, when the writing operation is performed on a memory cell adjacent to the second impurity diffusion layer, the channel potential of the other unselected memory cell can be kept at the writing prevention voltage. Hence, erroneous writing to the unselected memory cell can assuredly be prevented, so that the memory cell unit is highly reliable and stably operable.

Where a plurality of memory cell units are arranged in a matrix configuration and each comprise either of the memory cell units described above, the selection transistors of the memory cell units each have a breakdown voltage not lower than the writing prevention voltage to be applied between the drain diffusion layer and the source diffusion layer. Particularly, when the writing operation is performed on the memory cell adjacent to the third impurity diffusion layer, the channel potential of the unselected memory cell can be kept at the writing prevention voltage. Hence, erroneous writing to the unselected memory cell can assuredly be prevented. Therefore, a nonvolatile semiconductor storage device can be provided which is highly reliable and stably operable.

As described above, the present invention is further directed to a nonvolatile semiconductor storage device, which includes a selection transistor having a sufficiently high breakdown voltage with respect to a bit line writing prevention voltage to be applied when electrons are injected into a charge storage layer of a memory cell, and is capable of assuredly preventing erroneous writing to an unselected memory cell.

Alternatively, a plurality of memory cell units are longitudinally and transversely arranged in a matrix configuration, and each comprise either of the memory cell units described above. A plurality of control gate lines are each provided by sequentially connecting control gates of memory cells provided in column-shaped semiconductor layers arranged longitudinally in each column of the matrix configuration, and are commonly connected. A plurality of bit lines are each provided by connecting drain diffusion layers of memory cell units provided in column-shaped semiconductor layers arranged transversely in each row of the matrix configuration. In this case, selection transistors of the memory cell units each have a breakdown voltage not lower than the writing prevention voltage to be applied between the drain diffusion layer and the source diffusion layer of the memory cell unit. Particularly, when the writing operation is performed on a memory cell adjacent to the third impurity diffusion layer, the channel potential of the unselected memory cell can be kept at not lower than the writing prevention voltage. Hence, erroneous writing to the unselected memory cell can assuredly be prevented. Therefore, a nonvolatile semiconductor device can be provided, which is highly reliable and stably operable.

Where an inventive liquid crystal display device comprises either of the semiconductor storage devices described above, erroneous writing to the semiconductor device can assuredly be prevented. Therefore, the liquid crystal display device is high reliable and stably operable.

### BRIEF DESCRIPTION OF THE DRAWINGS

FIG. 1 is a sectional view of an inventive memory cell unit taken perpendicularly to a semiconductor substrate;

FIG. 2 is an equivalent circuit diagram of the inventive memory cell unit;

FIG. 3 is a perspective view of a NAND memory cell unit provided in an inventive nonvolatile semiconductor storage device;

FIG. 4 is a plan view of a memory cell unit array including a plurality of nonvolatile memory elements according to the present invention;

FIGS. 5 to 24 are sectional views taken along a line A-A′ in FIG. 4 for explaining an exemplary production process for a memory cell unit array according to the present invention;

FIG. 25 is a block diagram of a memory cell unit array according to a second embodiment of the present invention;

FIG. 26 is an equivalent circuit diagram of the memory cell unit array shown in FIG. 25;

FIG. 27 is a graph illustrating a change in the channel potential of a memory cell in a first writing operation according to the second embodiment;

FIG. 28 is a graph illustrating a change in the channel potential of a memory cell in a second writing operation according to the second embodiment;

FIG. 29 is a block diagram of a memory cell unit array according to a third embodiment of the present invention;

FIG. 30 is an equivalent circuit diagram of the memory cell unit array shown in FIG. 29;

FIG. 31 is a circuit diagram illustrating a first capacitance network formed in a column-shaped semiconductor layer in a third writing operation according to the third embodiment;

FIG. 32 is a graph illustrating a change in the channel potential of a memory cell M1 in the third writing operation according to the third embodiment;

FIG. 33 is a circuit diagram illustrating a second capacitance network formed in the column-shaped semiconductor layer in the third writing operation according to the third embodiment;

FIG. 34 is a graph illustrating a change in the channel potential of a memory cell M2 in the third writing operation according to the third embodiment;

FIG. 35 is a circuit diagram illustrating a first capacitance network formed in the column-shaped semiconductor layer in a fourth writing operation according to the third embodiment;

FIG. 36 is a graph illustrating a change in the channel potential of the memory cell M1 in the fourth writing operation according to the third embodiment;

FIG. 37 is a circuit diagram illustrating a second capacitance network formed in the column-shaped semiconductor layer in the fourth writing operation according to the third embodiment;

FIG. 38 is a graph illustrating a change in the channel potential of the memory cell M2 in the fourth writing operation according to the third embodiment;

FIG. 39 is a schematic diagram illustrating the construction of a liquid crystal display device (fourth embodiment) including the inventive semiconductor storage device;

FIG. 40 is a sectional view illustrating a conventional EEPROM in which a column-shaped semiconductor layer is electrically connected to a semiconductor substrate;

FIG. 41 is a sectional view illustrating a conventional EEPROM in which a column-shaped semiconductor layer is electrically isolated from a semiconductor substrate;

FIG. 42 is an equivalent circuit diagram of a conventional NAND memory cell unit;

FIG. 43 is a block diagram of a conventional memory cell unit array;

FIG. 44 is an equivalent circuit diagram of the memory cell unit array shown in FIG. 43;

FIG. 45 is a graph illustrating a change in the channel potential observed with time when a writing operation is performed on a memory cell of the memory cell unit array shown in FIG. 43;

FIG. 46 is a block diagram illustrating another conventional memory cell unit array;

FIG. 47 is an equivalent circuit diagram of the memory cell unit array shown in FIG. 46;

FIG. 48 is a circuit diagram illustrating a first capacitance network formed in a column-shaped semiconductor layer of a memory cell unit of the memory cell unit array of FIG. 46;

FIG. 49 is a graph illustrating a change in the channel potential observed with time when a writing operation is performed on the memory cell shown in the circuit diagram of FIG. 48;

FIG. 50 is a circuit diagram illustrating a second capacitance network formed in the column-shaped semiconductor layer of the memory cell unit of the memory cell unit array of FIG. 46; and

FIG. 51 is a graph illustrating a change in the channel potential observed with time when the writing operation is performed on the memory cell shown in the circuit diagram of FIG. 50.

### DETAILED DESCRIPTION OF THE INVENTION

A memory cell unit according to the present invention comprises: a semiconductor substrate having a source diffusion layer provided in a surface thereof; a column-shaped semiconductor layer provided on the source diffusion layer as extending perpendicularly to the semiconductor substrate and having a drain diffusion layer provided in an uppermost portion thereof; a memory cell arrangement which includes a plurality of memory cells arranged in series with the intervention of a first impurity diffusion layer on the column-shaped semiconductor layer perpendicularly to the substrate, the memory cells each having a charge storage layer and a control gate; a first selection transistor connected to one end of the memory cell arrangement with the intervention of a second impurity diffusion layer and connected to the drain diffusion layer; and a second selection transistor connected to the other end of the memory cell arrangement with the intervention of a third impurity diffusion layer and connected to the source diffusion layer; wherein a distance between the third impurity diffusion layer and the source diffusion layer is greater than a distance between impurity diffusion layers disposed on opposite sides of each of the memory cells, whereby punch-through of the second selection transistor is prevented when a writing prevention voltage is applied between the source diffusion layer and the first impurity diffusion layer.

In the inventive memory cell unit, the column-shaped semiconductor layer may be electrically isolated or connected to the semiconductor substrate. The distance between the third impurity diffusion layer and the source diffusion layer is greater than the distance between the impurity diffusion layers disposed on the opposite sides of each of the memory cells. Therefore, the punch-through of the second selection transistor can be prevented when the writing prevention voltage is applied between the source diffusion layer and the first impurity diffusion layer.

Further, a distance between the drain diffusion layer and the second impurity diffusion layer may be greater than the distance between the impurity diffusion layers disposed on the opposite sides of each of the memory cells. Therefore, the punch-through of the first selection transistor can be prevented when the writing prevention voltage is applied between the drain diffusion layer and the second impurity diffusion layer.

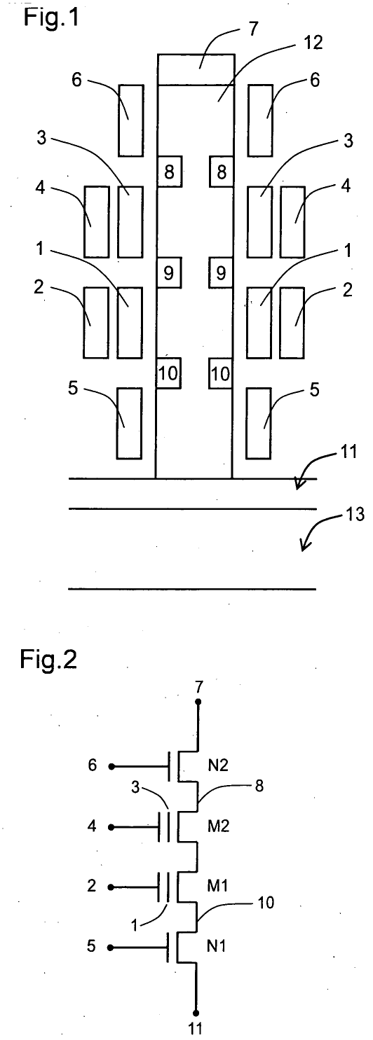

The distance between the third impurity diffusion layer and the source diffusion layer herein means a minimum distance between a third impurity diffusion layer 10 and a source diffusion layer 11 as shown in FIG. 1.

The distance between the impurity diffusion layers disposed on the opposite sides of each of the memory cells herein means a minimum distance between a first impurity diffusion layer 9 and a second impurity diffusion layer 8 or a minimum distance between the first impurity diffusion layer 9 and the third impurity diffusion layer 10 as shown in FIG. 1.

The writing prevention voltage herein means a voltage to be applied to the drain diffusion layer of an unselected memory cell unit when a writing operation is performed on a memory cell. When electrons are injected into the charge storage layer of a selected memory cell for the writing, a positive voltage is applied as a writing voltage to a control gate line connected to the control gate of the selected memory cell. Therefore, the writing voltage is also applied to the control gate of an unselected memory cell which shares the control gate line with the selected memory cell, so that the writing to the unselected memory cell should be prevented. Hence, a positive high voltage is applied to the drain diffusion layer of a memory cell unit including the unselected memory cell to prevent the electron injection which may otherwise occur due to a voltage difference between the drain diffusion layer and the control gate. In this case, the voltage applied to the drain diffusion layer is the writing prevention voltage.

The punch-through herein means a phenomenon such that, when a high voltage is applied to a transistor having a short source-drain distance (channel length), a drain side depletion layer and a source side depletion layer are connected to each other and an electric current flows between the source and the drain without formation of a channel below the gate. In general, when a voltage greater than the source-drain breakdown voltage of the transistor (i.e., the maximum voltage allowed to be applied between the source and the drain when the transistor is off) is applied, the electric current flowing between the source and the drain is steeply increased even with the transistor being off. This results in breakdown of the transistor. When the breakdown occurs, the source-drain voltage is reduced to a level equivalent to the breakdown voltage. In the case of a minute transistor having a short channel length, the breakdown voltage is determined by the punch-through. For improvement of the breakdown voltage against the punch-through (punch-through breakdown voltage), it is necessary to increase the channel length of the transistor. With a greater channel length, the connection between the drain side depletion layer and the source side depletion layer occurs only when a high voltage is applied. Therefore, the punch-through can be prevented.

The breakdown voltage of the first selection transistor herein means a maximum voltage to be sustained between the drain diffusion layer and the second impurity diffusion layer when the first selection transistor is off. The breakdown voltage of the second selection transistor herein means a maximum voltage to be sustained between the third impurity diffusion layer and the source diffusion layer when the second selection transistor is off.

Therefore, the punch-through of the first selection transistor herein means a phenomenon such that, when the transistor is off, a depletion layer on the side of the second impurity diffusion layer and a depletion layer on the side of the drain diffusion layer are connected to each other, and an electric current flows through the channel of the transistor. The punch-through of the second selection transistor herein means a phenomenon such that, when the transistor is off, a depletion layer on the side of the source diffusion layer and a depletion layer on the side of the third impurity diffusion layer are connected to each other, and an electric current flows through the channel of the transistor.

In other words, a feature of the inventive memory cell unit is that the second selection transistor has a breakdown voltage which is not lower than a level equivalent to a difference between the writing prevention voltage to be applied to the drain diffusion layer of the memory cell unit having the memory cell not subjected to the electron injection and the voltage to be applied to the source diffusion layer in the writing operation. Further, the first selection transistor has a breakdown voltage which is not lower than a level equivalent to a difference between the writing prevention voltage to be applied to the drain diffusion layer of the memory cell unit having the memory cell not subjected to the electron injection and the voltage to be applied to the source diffusion layer in the writing operation.

A nonvolatile semiconductor storage device according to the present invention may comprise a plurality of memory cell units arranged longitudinally and transversely in a matrix configuration, wherein the memory cell units each comprise the memory cell unit described above.

A nonvolatile semiconductor storage device according to the present invention may comprise a plurality of memory cell units longitudinally and transversely arranged in a matrix configuration and each comprising the memory cell unit described above, wherein a plurality of control gate lines are each provided by sequentially connecting control gates of memory cells provided in column-shaped semiconductor layers arranged longitudinally in each column of the matrix configuration and are commonly connected, wherein a plurality of bit lines are each provided by connecting drain diffusion layers of memory cell units provided in column-shaped semiconductor layers arranged transversely in each row of the matrix configuration.

A liquid crystal display device according to the present invention comprises either of the nonvolatile semiconductor storage devices.

With reference to the attached drawings, the present invention will hereinafter be described in detail by way of embodiments thereof. However, it should be understood that the invention be not limited to these embodiments.

### DESCRIPTION OF THE PREFERRED EMBODIMENTS

First Embodiment

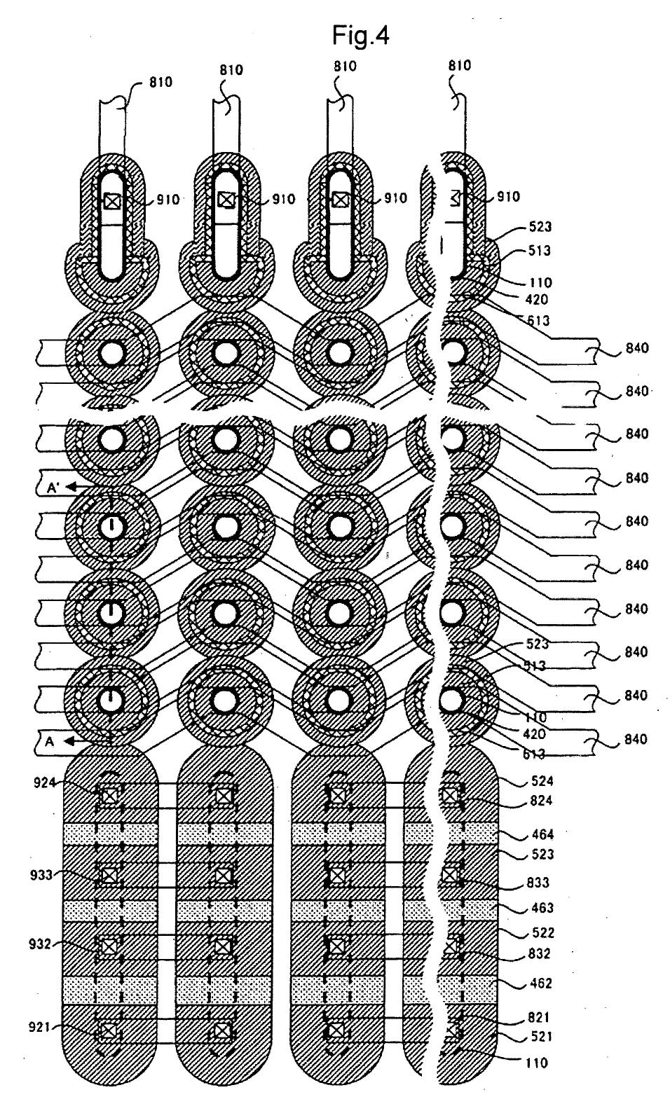

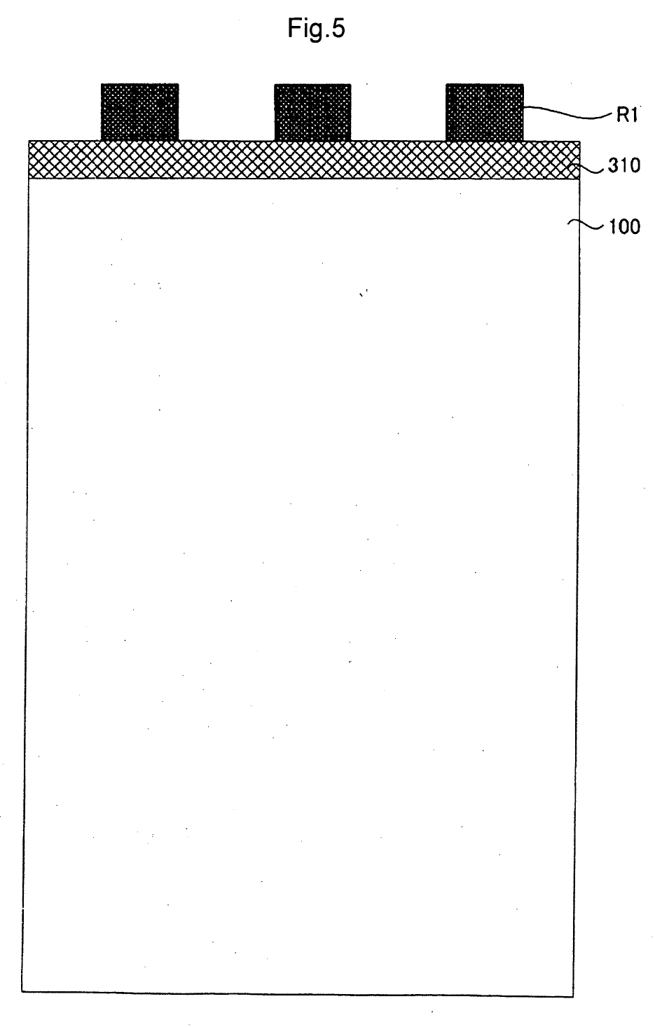

With reference to FIGS. 5 to 24, an explanation will be given to an exemplary production process for producing NAND memory cell units provided in a nonvolatile semiconductor storage device according to the present invention. The NAND memory cell units to be produced in this embodiment each include an island semiconductor layer formed, for example, by processing a semiconductor substrate into a sea-island configuration and having a peripheral surface serving as an active region, selection transistors provided in association with upper and lower portions of the island semiconductor layer, and a plurality of memory cells (e.g., two memory cells) arranged in series along the island semiconductor layer between the selection transistors and each including a floating gate constituted by a tunnel oxide film and a charge storage layer provided on the active region of the island semiconductor layer. The island semiconductor layer is electrically floated from the semiconductor substrate, and active regions of the memory cells are electrically floated from each other. FIG. 4 is a plan view of a memory cell unit array including a plurality of such NAND memory cell units according to the present invention. FIGS. 5 to 24 are sectional views taken along a line A-A′ in FIG. 4 for explaining the production process for the memory cell unit array shown in FIG. 4.

A silicon nitride film (first insulation film) 310 having a thickness of 200 to 2,000 nm is first formed on a surface of a p-type silicon substrate (semiconductor substrate) 100. Then, a resist film is formed on the silicon nitride film 310 and patterned by a known photolithography technique for formation of a resist mask R1 (FIG. 5).

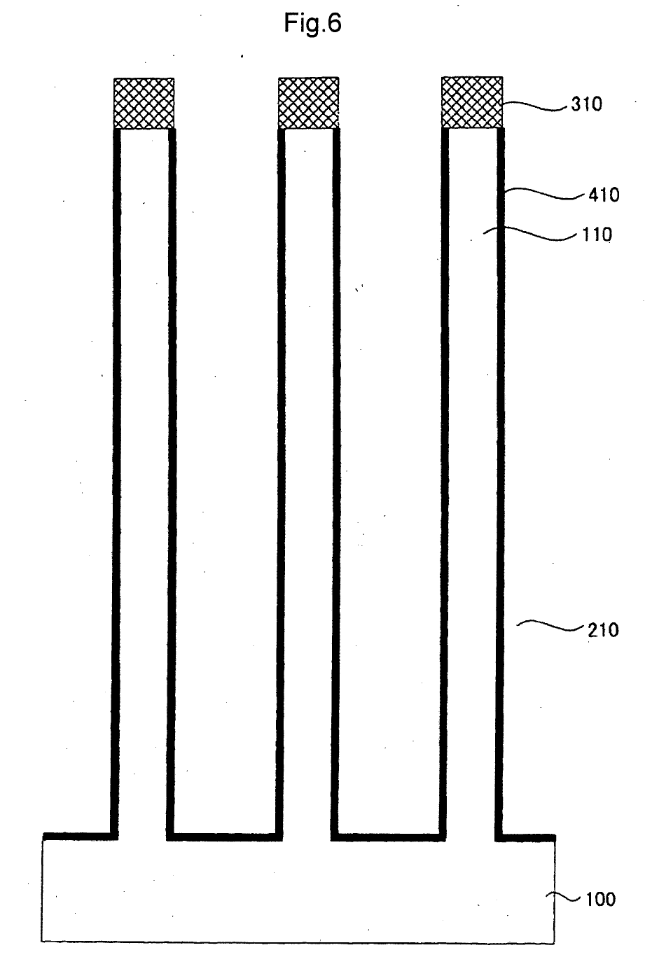

With the use of the resist mask R1, the silicon nitride film (first insulation film) 310 is etched by reactive ion etching. Then, the p-type silicon substrate (semiconductor substrate) 100 is etched to a depth of 2,000 to 20,000 nm by reactive ion etching by employing the resulting silicon nitride films (first insulation films) 310 as a mask, whereby a first lattice trench 210 is formed. Thus, a portion of the p-type silicon substrate 100 is divided into a plurality of island semiconductor layers 110 arranged in a sea-island configuration. Thereafter, an upper surface of the p-type silicon substrate 100 and peripheral surfaces of the respective island semiconductor layers 110 are thermally oxidized, whereby a thermal oxide film (second insulation film) 410 is formed (FIG. 6).

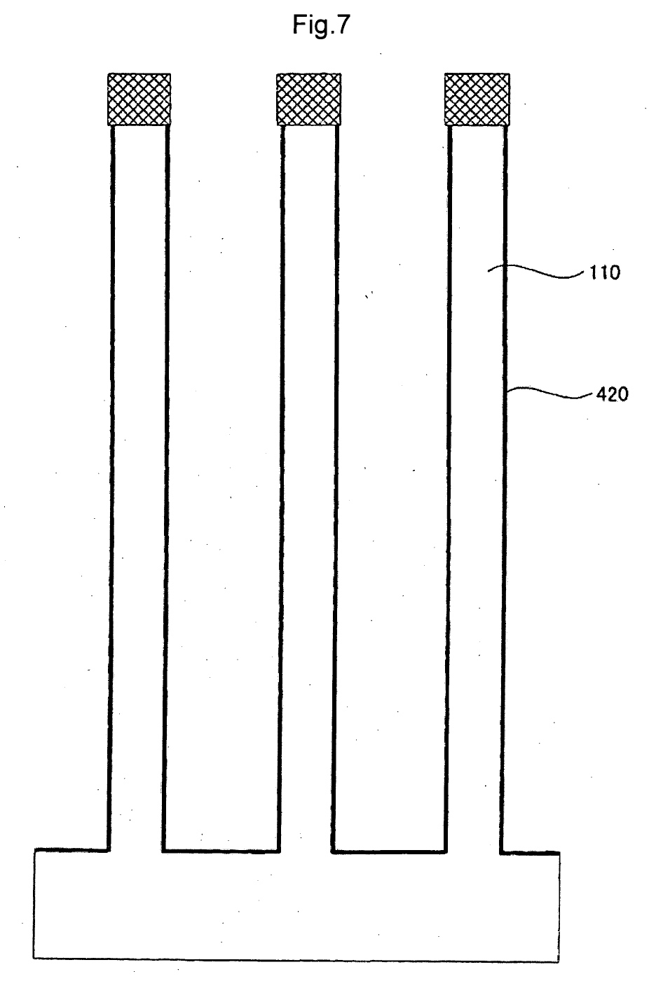

After portions of the thermal oxide film (second insulation film) 410 present in the peripheral surfaces of the island semiconductor layers 110 are selectively etched away, for example, by isotropic etching, channel ions are introduced into the peripheral surfaces of the respective island semiconductor layers 110 as required by oblique ion implantation. Alternatively, the introduction of the channel ions may be achieved by forming a boron-containing oxide film on the peripheral surfaces of the island semiconductor layers 110 by CVD and diffusing boron into the peripheral surfaces from the oxide film rather than by the channel ion implantation. In turn, silicon oxide films (third insulation films) 420 each having a thickness of about 10 m are formed as tunnel oxide films in the peripheral surfaces of the respective island semiconductor layers 110, for example, by thermal oxidization (FIG. 7). The tunnel oxide films are not limited to the thermal oxide films, but may be CVD oxide films or nitrogen oxide films. It is merely necessary to form the third insulation films at least on the active regions of the island semiconductor layers 110, but the third insulation films may be formed as entirely covering the peripheral surfaces and upper surfaces of the island semiconductor layers 110 and the surface of the semiconductor substrate 100.

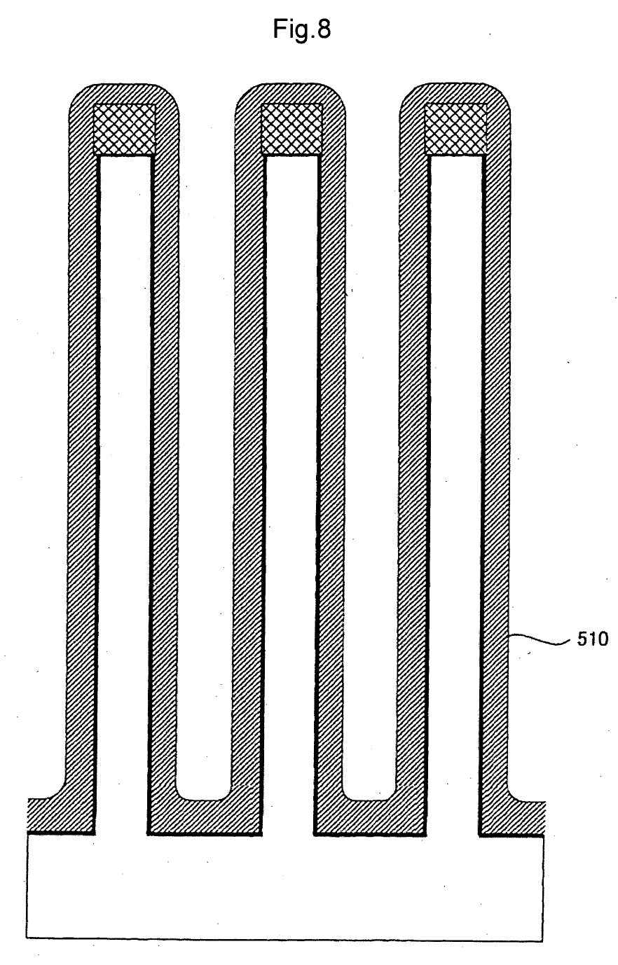

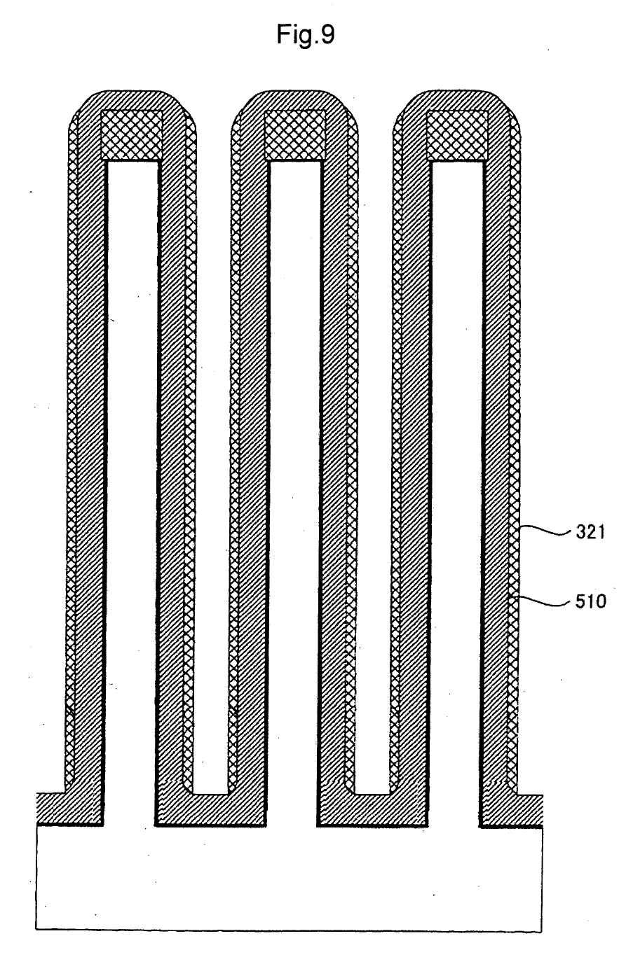

Subsequently, a polycrystalline silicon film (first electrically conductive film) 510 is formed as entirely covering the peripheral surfaces and upper surfaces of the island semiconductor layers 110 and the surface of the semiconductor substrate 100 (FIG. 8). However, it is merely necessary to form the first electrically conductive film at least on the peripheral surfaces of the island semiconductor layers 110. Thereafter, a silicon nitride film (fourth insulation film) 321 is formed by CVD, and then selectively etched away, for example, by reactive ion etching, so that portions of the silicon nitride film (fourth insulation film) 321 are left as side wall spacers on the peripheral surface portions of the polycrystalline silicon film (first electrically conductive film) 510 (FIG. 9).

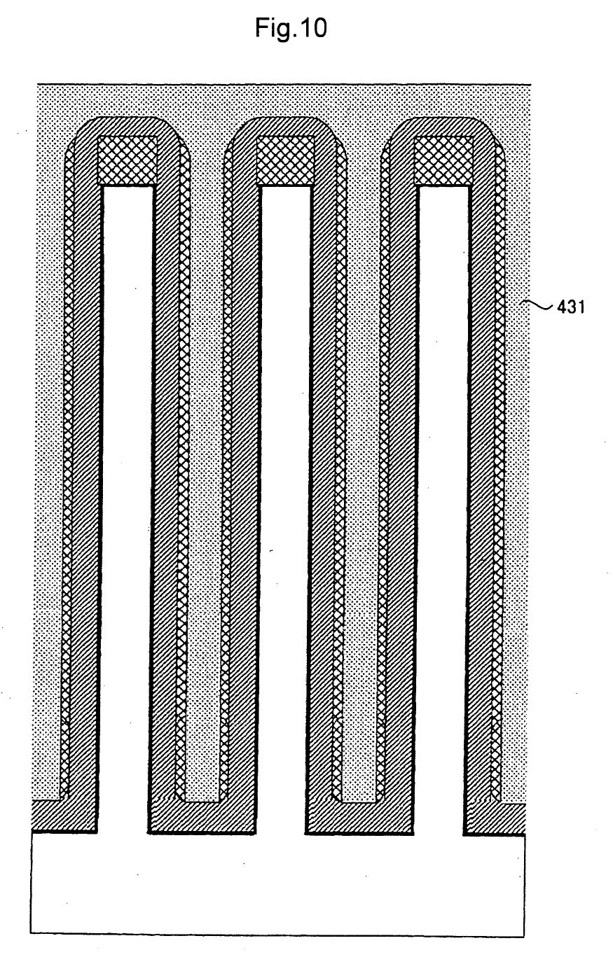

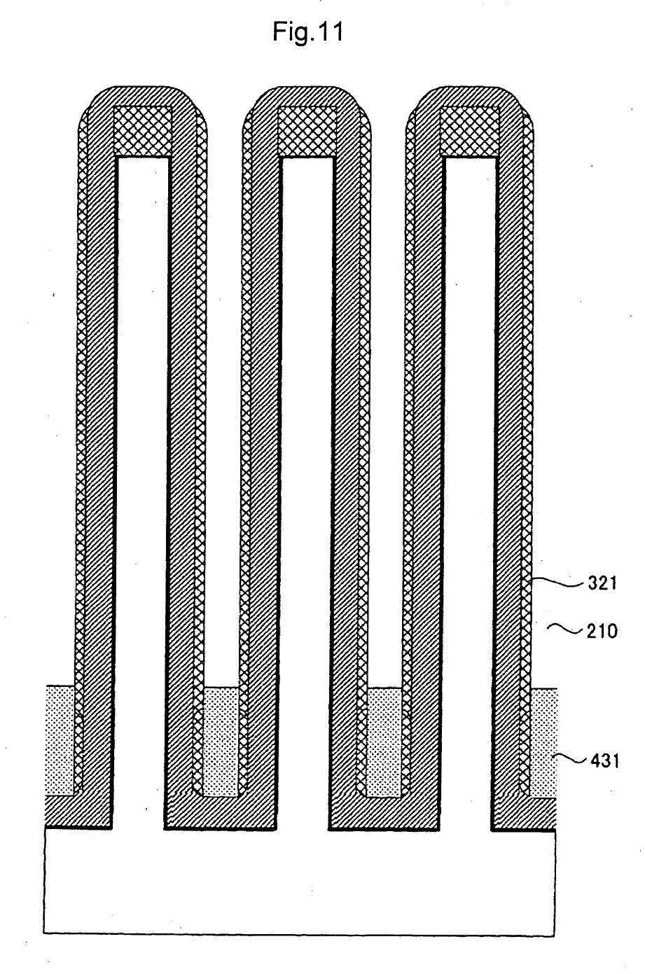

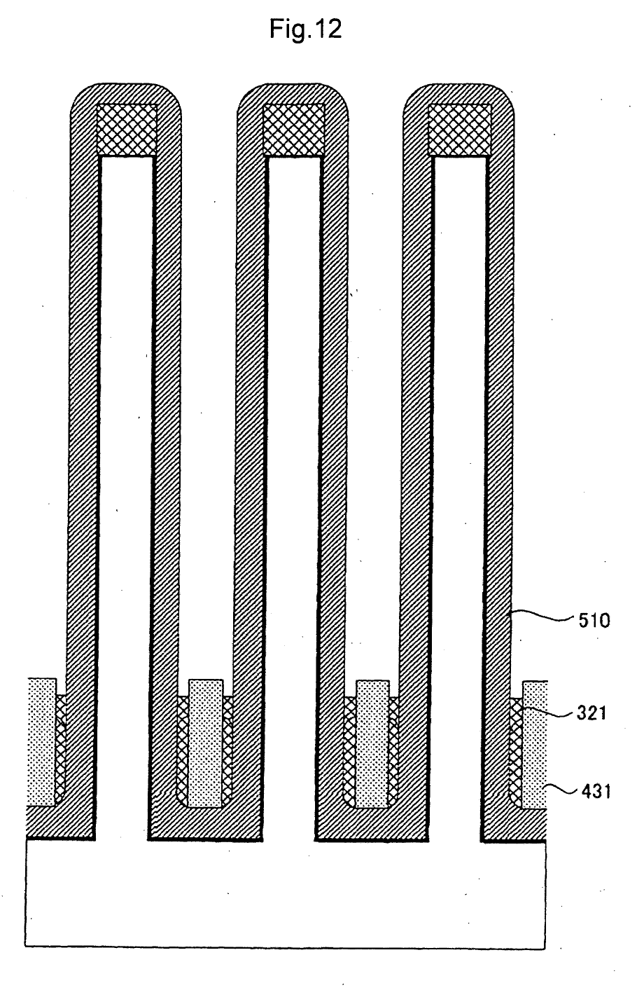

A silicon oxide film (fifth insulation film) 431 is formed in the first lattice trench 210 by CVD (FIG. 10). The silicon oxide film (fifth insulation film) 431 is partly removed so as to fill the first lattice trench 210 to a desired depth (FIG. 11). The silicon nitride films (fourth insulation films) 321 are partly etched away by isotropic etching by employing the silicon oxide film (fifth insulation film) 431 as a mask, so that portions of the silicon nitride films (fourth insulation films) 321 present between the silicon oxide film (fifth insulation film) 431 and the polycrystalline silicon film (first electrically conductive film) 510 are left (FIG. 12). At this time, the silicon nitride films (fourth insulation films) 321 are recessed from an upper surface of the silicon oxide film (fifth insulation film) 431. Then, silicon oxide films (sixth insulation films) 441 are formed in the recesses. At this time, the silicon oxide films (sixth insulation films) 441 each have a thickness not smaller than about one half the thickness of the silicon nitride films (fourth insulation films) 321 to fill the recesses. Further, portions of the oxide films 441 present on the polycrystalline silicon films (first electrically conductive films) 510 outside the recesses are removed, for example, by isotropic etching. The silicon oxide films (sixth insulation films) 441 are present in the recesses, so that the silicon nitride films (fourth insulation films) 321 are confined by the silicon oxide films (fifth insulation films) 431 and the silicon oxide films (sixth insulation films) 441.

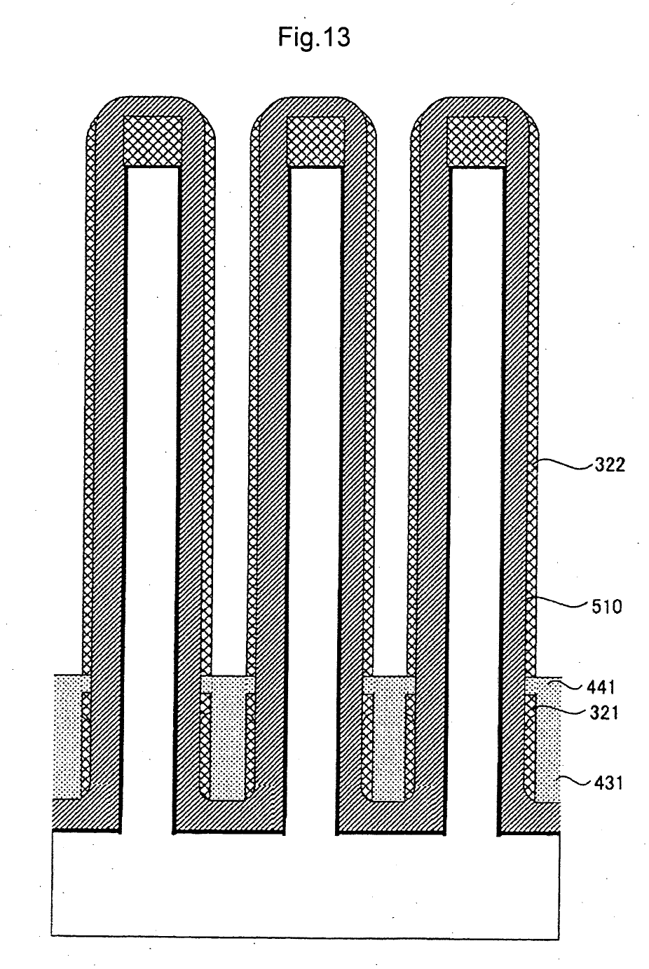

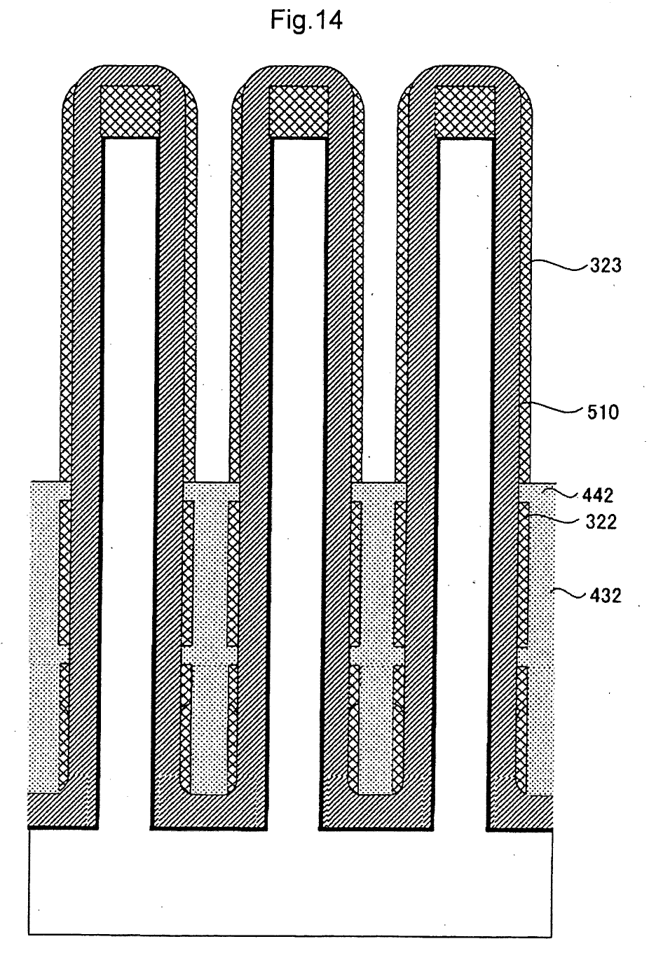

In turn, a silicon nitride film (fourth insulation film) 322 is formed in the same manner as described above by CVD, and selectively etched away by reactive ion etching, so that portions of the silicon nitride film (fourth insulation film) 322 are left as side wall spacers on the peripheral surface portions of the polycrystalline silicon film (first electrically conductive film) 510 (FIG. 13). After a silicon oxide film (fifth insulation film) 432 is formed in the first lattice trench 210 in substantially the same manner as described above, silicon oxide films (sixth insulation films) 442 are formed in recesses above the silicon nitride films (fourth insulation films) 322 provided as the side wall spacers in the same manner as described above. Then, silicon nitride films (fourth insulation films) 323 are formed as side wall spacers on the peripheral surface portions of the polycrystalline silicon film (first electrically conductive film) 510 in the same manner as described above (FIG. 14).

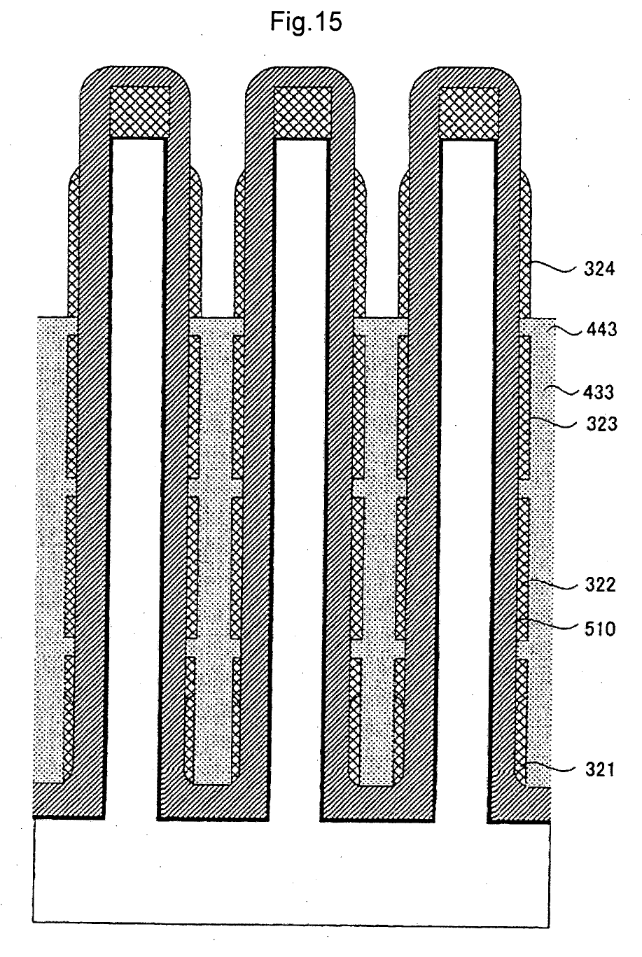

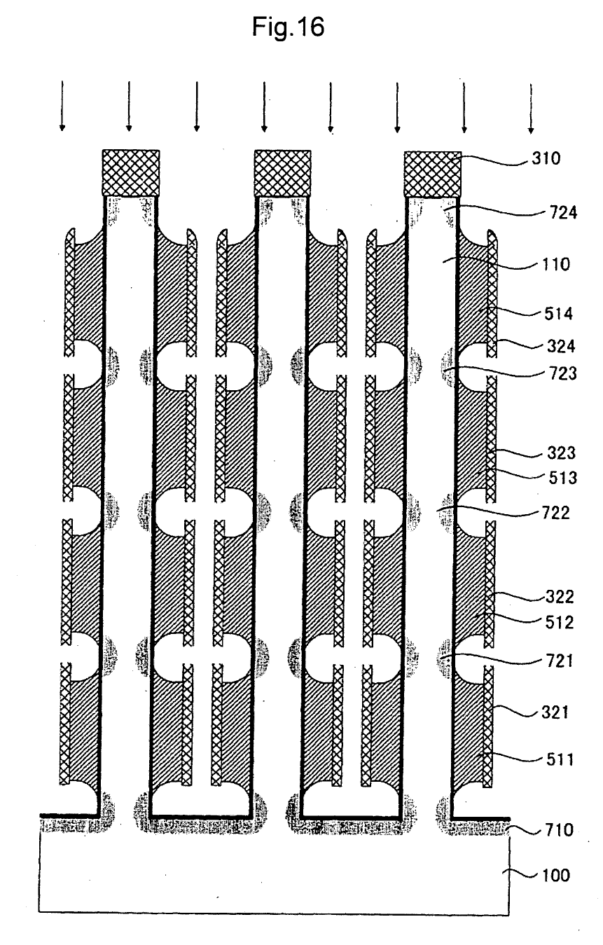

By repeating these steps, the plural silicon nitride films (fourth insulation films) 321 to 324 are formed as the side wall spacers on each of the peripheral surface portions of the polycrystalline silicon film (first electrically conductive film) 510 (FIG. 15). Then, the peripheral surface portions of the polycrystalline silicon film (first electrically conductive film) 510 are each divided into a plurality of polycrystalline silicon films (first electrically conductive films) 511 to 514 by isotropic etching (FIG. 16). Alternatively, the division of the polycrystalline silicon film (first electrically conductive film) 510 may be achieved by thermal oxidation by employing the silicon nitride films (fourth insulation films) 321 to 324 as a mask. Further, the etching and the thermal oxidation may be employed in combination for the division of the polycrystalline silicon film 510. An impurity is introduced into portions of the island semiconductor layers 110 and portions of the semiconductor substrate 100 in self-alignment with the polycrystalline silicon films (first electrically conductive films) 511 to 514 and the silicon nitride films (first insulation films) 310 for formation of N-type semiconductor layers 721 to 724 and impurity diffusion layers 710. At this time, the impurity concentration of the impurity diffusion layers 710 which thereafter serve as a first interconnection layer (source) may be adjusted by an ion implantation method (FIG. 16).

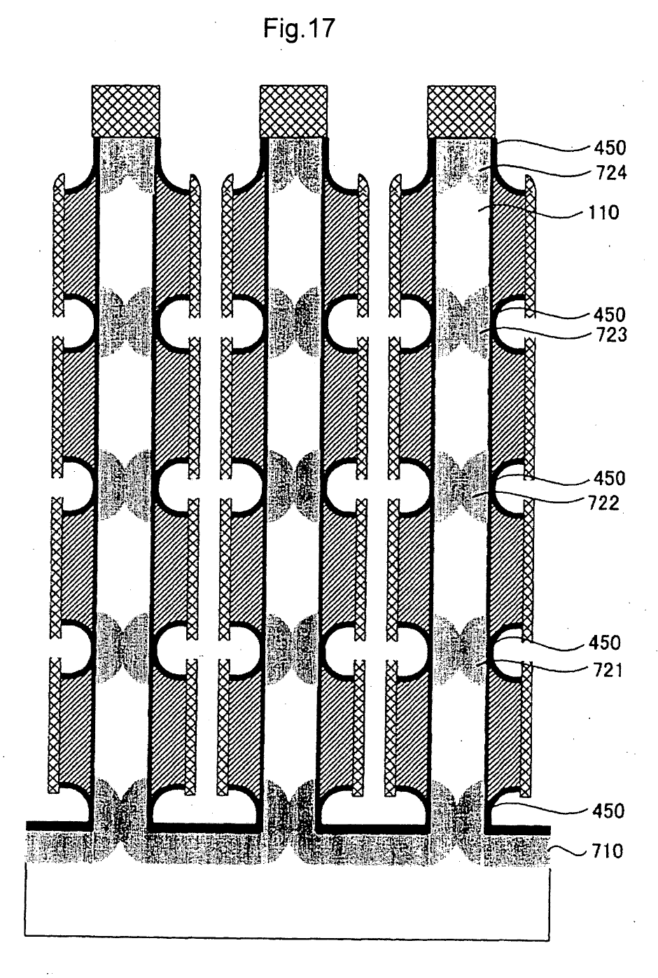

The formation of the impurity diffusion layers 710 for the first interconnection layer is not necessarily required to be carried out simultaneously with the formation of the N-type semiconductor layers 721 to 724. For example, the formation of the impurity diffusion layers 710 for the first interconnection layer may be achieved by ion implantation after the formation of the thermal oxide film (second insulation film) 410 or after the formation of the silicon oxide films (third insulation films) 420. Further, the ion introduction may be repeated a plurality of times at the aforesaid time points. Thereafter, silicon oxide films (seventh insulation films) 450 are formed in exposed surfaces of the polycrystalline silicon films (first electrically conductive films) 511 to 514, for example, by thermal oxidation. At this time, the thermal treatment diffuses the impurity diffusion layers 710 and 721 to 724 into the island semiconductor layers 110, whereby the resulting p-type regions in the island semiconductor layers 110 are electrically floated (FIG. 17). The introduction of the impurity in the polycrystalline silicon films (first electrically conductive films) 511 to 514 may be carried out when the polycrystalline silicon film (first electrically conductive film) 510 is formed, or when the impurity is introduced into the island semiconductor layers 110. The timing of the impurity introduction is not particularly limited, as long as it is possible to impart the polycrystalline silicon films 511 to 514 with electrical conductivity.

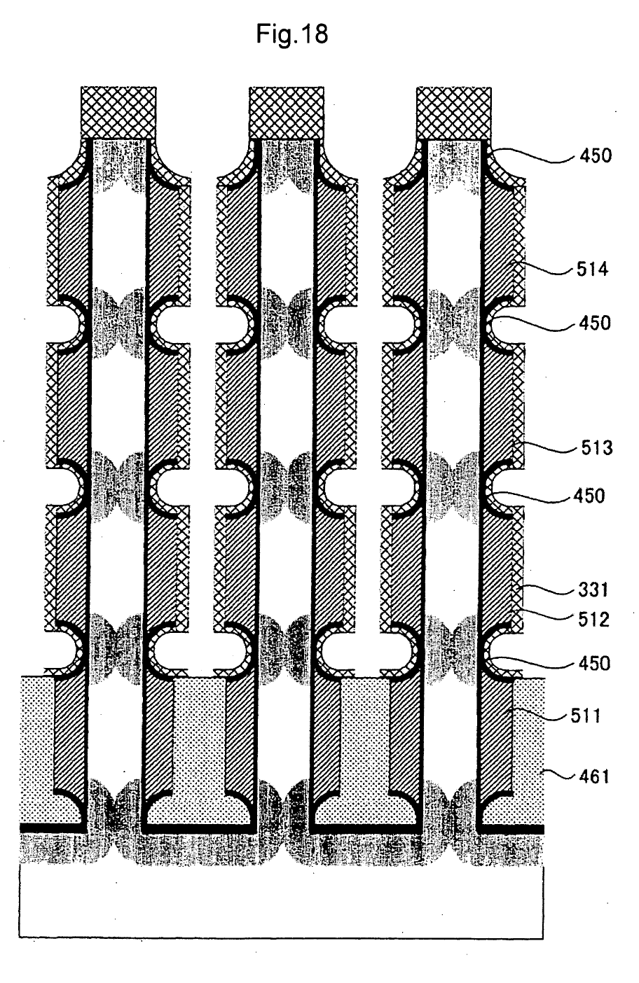

After the silicon nitride side wall spacers (fourth insulation films) 321 to 324 are removed, for example, by isotropic etching, a silicon oxide film (eighth insulation film) 461 is formed by CVD and partly etched by anisotropic etching and isotropic etching, whereby the peripheral surfaces of the polycrystalline silicon films (first electrically conductive films) 511 are covered with the resulting silicon oxide film (eighth insulation film) 461. In turn, silicon nitride films (ninth insulation films) 331 are formed as side wall spacers on the polycrystalline silicon films (first electrically conductive films) 512 to 514 and the silicon oxide films (seventh insulation films) 450 (FIG. 18).

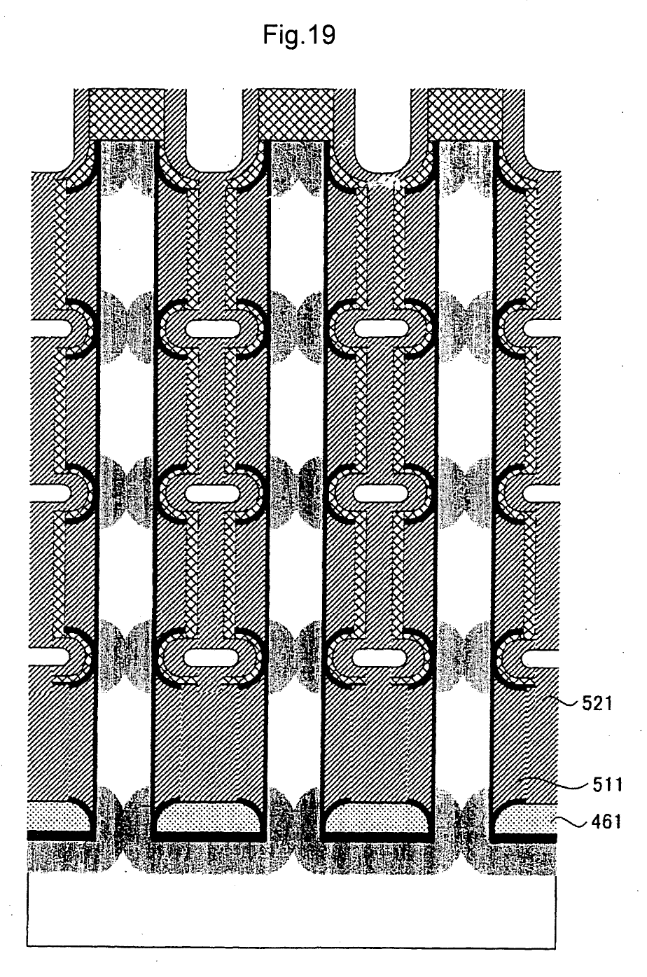

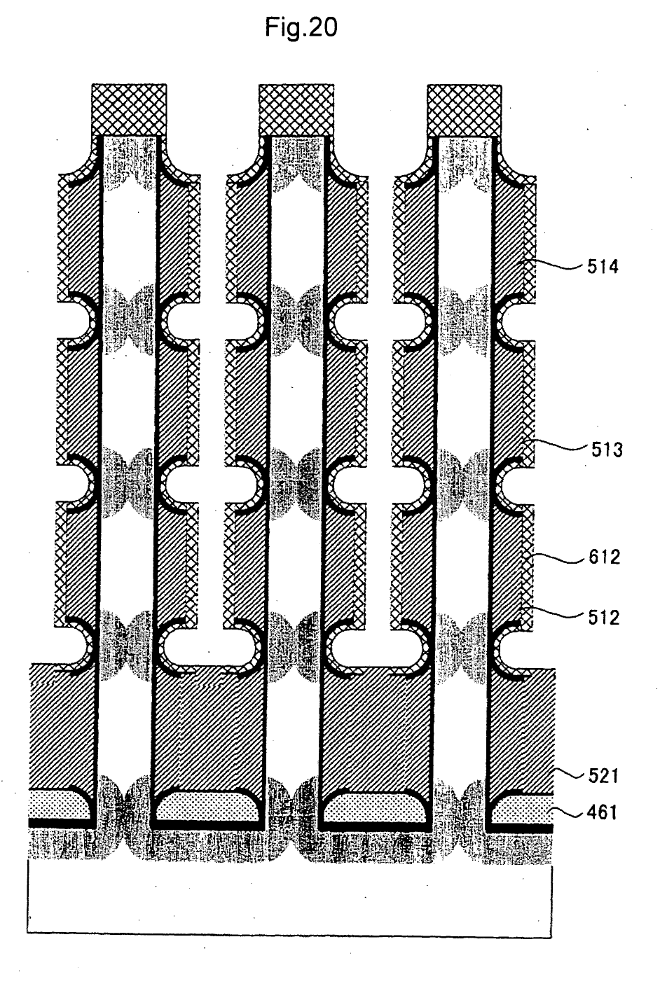

Subsequently, the silicon oxide film (eighth insulation film) 461 is etched back so as to expose the peripheral surfaces of the polycrystalline silicon films (first electrically conductive films) 511, and then polycrystalline silicon films (second electrically conductive films) 521 are formed on the peripheral surfaces of the polycrystalline silicon films (first electrically conductive films) 511 (FIG. 19). Thereafter, second trenches 220 are formed in the p-type silicon substrate (semiconductor substrate) 100 in self-alignment with the polycrystalline silicon films (second electrically conductive films) 521 for isolation of the impurity diffusion layers 710. That is, isolation portions for the first interconnection layer are formed in self-alignment with isolation portions for the second electrically conductive films. In turn, the polycrystalline silicon films (second electrically conductive films) 521 are etched back to such an extent as to respectively contact the polycrystalline silicon films (first electrically conductive films) 511. The resulting polycrystalline silicon films (second electrically conductive films) 521 each serve as a selection gate. At this time, a selection gate line (second interconnection layer) is formed as continuously extending along the line A-A′ in FIG. 4 without the need for a masking step, where a distance between the island semiconductor layers 110 as measured along the line A-A′ is set at not greater than a predetermined distance. Thereafter, a silicon oxide film (eighth insulation film) 462 is formed and partly etched by anisotropic etching and isotropic etching, whereby side surfaces and upper surfaces of the polycrystalline silicon films (second electrically conductive films) 521 are covered with the resulting silicon oxide films (eighth insulation films) 462. Then, the silicon nitride side wall spacers (ninth insulation films) 331 are removed by isotropic etching, and inter-layer insulation films 612 are formed on exposed peripheral surfaces of the polycrystalline silicon films (first electrically conductive films) 512 to 514 (FIG. 20). The inter-layer insulation films 612 may be, for example, ONO films.

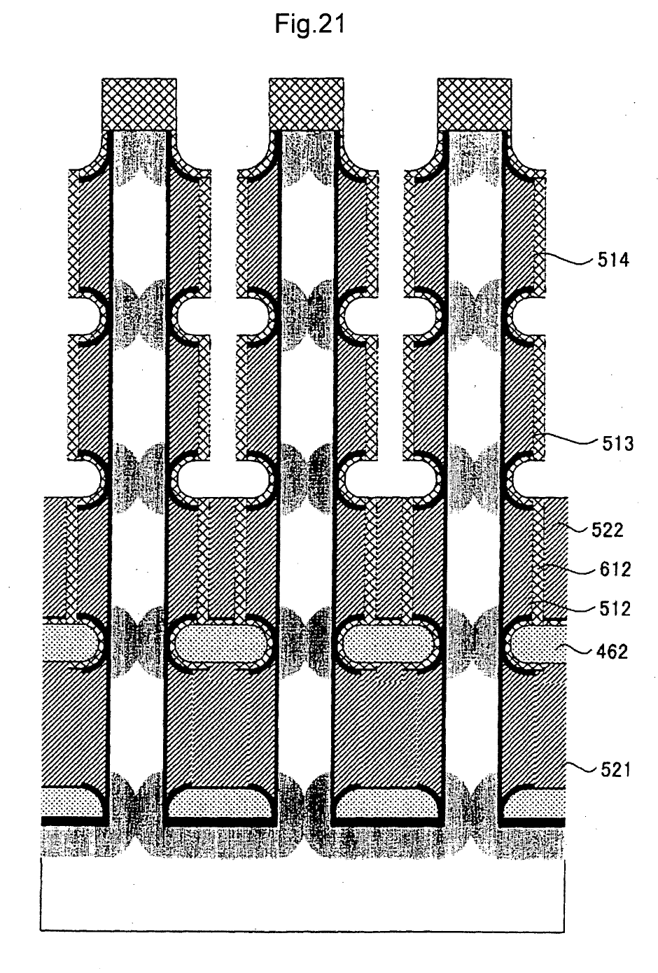

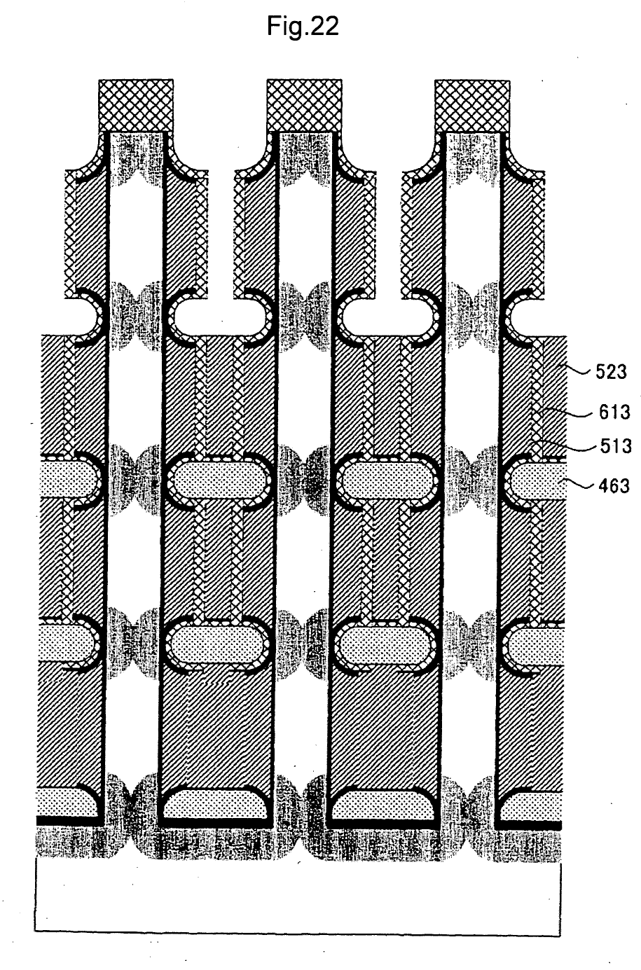

In turn, a polycrystalline silicon film (second electrically conductive film) 522 is formed and etched back in the same manner as described above, whereby the peripheral surfaces of the polycrystalline silicon films (first electrically conductive films) 512 are covered with the resulting polycrystalline silicon films (second electrically conductive films) 522 with the intervention of the inter-layer insulation films 612 (FIG. 21). At this time, a control gate line (third interconnection layer) is formed as continuously extending along the line A-A′ in FIG. 4 without the need for a masking step, where the distance between the island semiconductor layers 110 as measured along the line A-A′ is set at not greater than the predetermined distance. Thereafter, a silicon oxide film (eighth insulation film) 463 is formed and partly etched by anisotropic etching and isotropic etching, whereby side surfaces and upper surfaces of the polycrystalline silicon films (second electrically conductive films) 522 are covered with the resulting silicon oxide films (eighth insulation films) 463. By repeating these steps, polycrystalline silicon films (second electrically conductive films) 523 are formed on the peripheral surfaces of the polycrystalline silicon films (first electrically conductive films) 513 with the intervention of inter-layer insulation films 613 (FIG. 22).

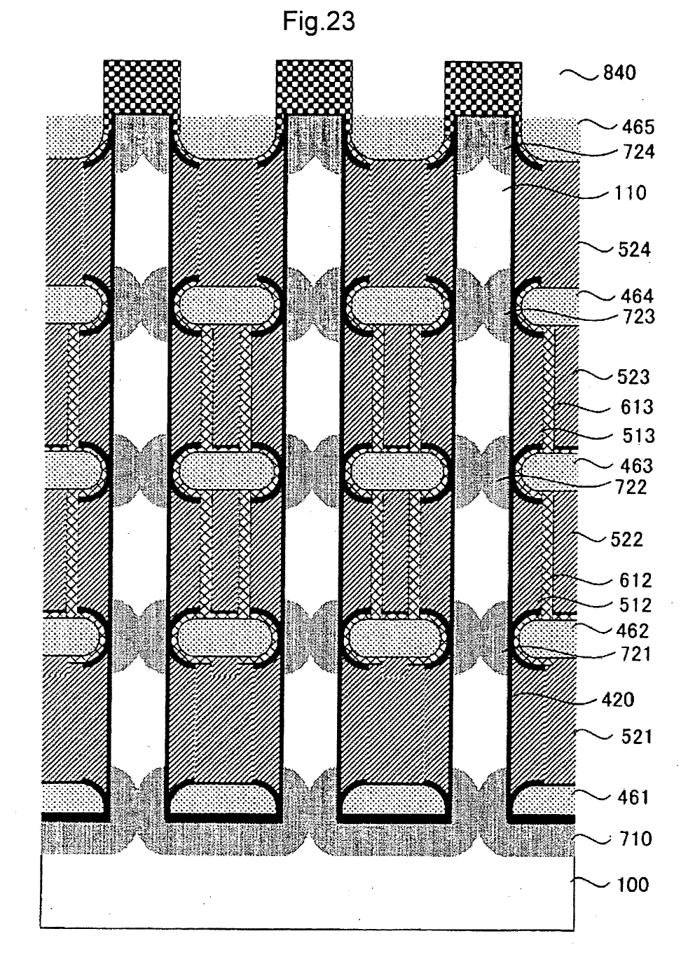

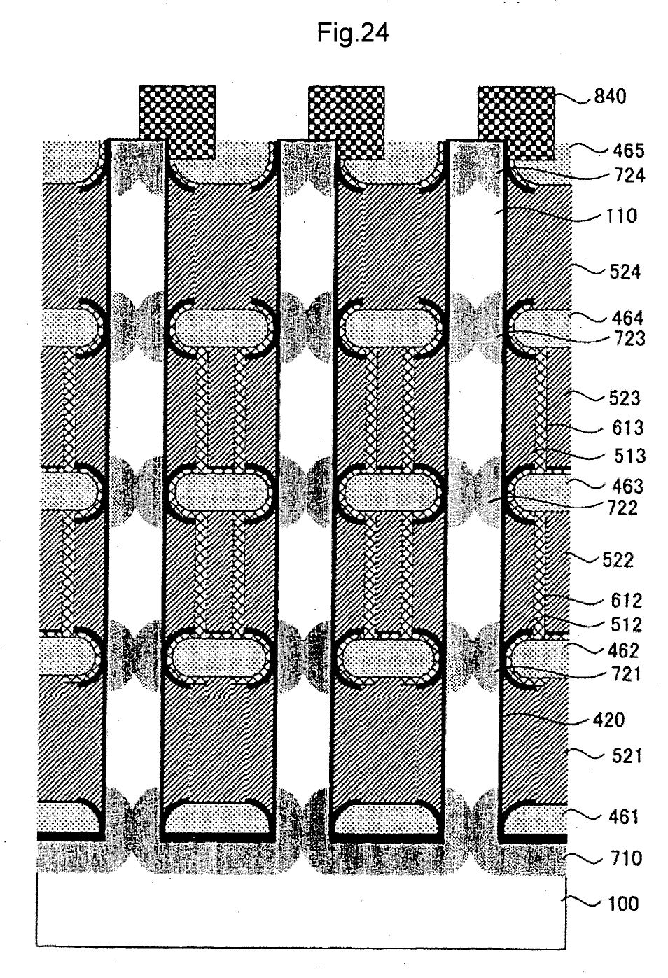

Then, oxide films (eighth insulation films) 464 are formed as covering side surfaces and upper surfaces of the polycrystalline silicon films (second electrically conductive films) 523. Polycrystalline silicon films (second electrically conductive films) 524 are formed on the peripheral surfaces of the uppermost polycrystalline silicon films (first electrically conductive films) 514, and etched back to such an extent as to respectively contact the uppermost polycrystalline silicon films (first electrically conductive films) 514 like the lowermost polycrystalline silicon films (first electrically conductive films) 511. A silicon oxide film (tenth insulation film) 465 is formed on the upper surfaces of the polycrystalline silicon films (second electrically conductive films) 524, and etched back or partly polished away by CMP, whereby the upper surfaces of the respective island semiconductor layers 110 respectively formed with the impurity diffusion layers 724 are exposed. Then, bit lines (fourth interconnection layers) 840 are formed as intersecting the second and third interconnection layers and connected to the upper portions of the island semiconductor layers 110 (FIG. 23). In FIG. 23, the fourth interconnection layers 840 are illustrated as disposed on the impurity diffusion layers 724 without misalignment. Even if the misalignment occurs, the fourth interconnection layers 840 can assuredly be connected to the impurity diffusion layers 724 as shown in FIG. 24.

Thereafter, an inter-level insulation film is formed, and then contact holes and metal interconnections are formed by known techniques. Thus, NAND memory cell units are produced, which each include charge storage layers each including the first electrically conductive film (polycrystalline silicon film) as a floating gate and have a memory function based on the charge injection state of the charge storage layers.

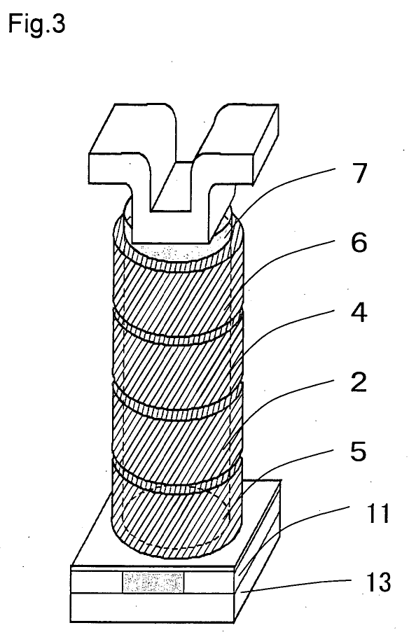

FIG. 1 is a sectional view of the memory cell unit of the nonvolatile semiconductor device produced in this embodiment as seen perpendicularly to the semiconductor substrate, and FIG. 2 is an equivalent circuit diagram of the memory cell unit. FIG. 3 is a perspective view illustrating the physical shape of the memory cell unit shown in FIG. 1. The NAND memory cell unit (flash memory) includes two memory cells M1, M2 arranged in series, and selection transistors N1, N2 disposed on opposite sides of the memory cells.

In the NAND memory cell unit, the selection transistor disposed on a source line side has a source-drain breakdown voltage VB1 which is not lower than a level equivalent to a difference between a voltage applied to a source line and a writing prevention voltage to be applied to a bit line when a writing operation is performed. By allowing the source side selection transistor to have a channel length at least greater than the channel lengths of the memory cell transistors, the source side selection transistor of the NAND memory cell unit has the required breakdown voltage. Thus, the punch-through breakdown voltage can be increased.

In the NAND memory cell unit produced by the production process according to this embodiment, the vertical length of the silicon nitride side wall spacer 321 is set greater than the vertical lengths of the silicon nitride side wall spacers 322, 323, whereby the vertical length of the polycrystalline silicon film 511 (the channel length of the selection transistor) is increased to greater than the vertical lengths of the polycrystalline silicon films 512, 513 (the channel lengths of the memory cell transistors). As a result, the channel length of the selection transistor can be set greater than the channel lengths of the memory cell transistors.

As described above, the inter-diffusion layer breakdown voltage of the selection transistor is determined by the channel length of the selection transistor. The channel length can be optimized by adjusting design and production parameters for the silicon nitride side wall spacers. Thus, the selection transistor can have desired characteristics.

While the design and production for imparting the source side selection transistor with the required breakdown voltage has been described, the drain side selection transistor may be designed and produced in the same manner as the source side selection transistor.

In the memory cell unit according to this embodiment, the column-shaped semiconductor layer is electrically isolated from the semiconductor substrate by an impurity diffusion layer having a conductivity opposite to the conductivity of the semiconductor substrate as shown in FIG. 1. However, the present invention is applicable not only to the case where the column-shaped semiconductor layer is electrically isolated from the semiconductor substrate but also to a case where the column-shaped semiconductor layer is electrically connected to the semiconductor substrate as shown in FIG. 40.

Second Embodiment

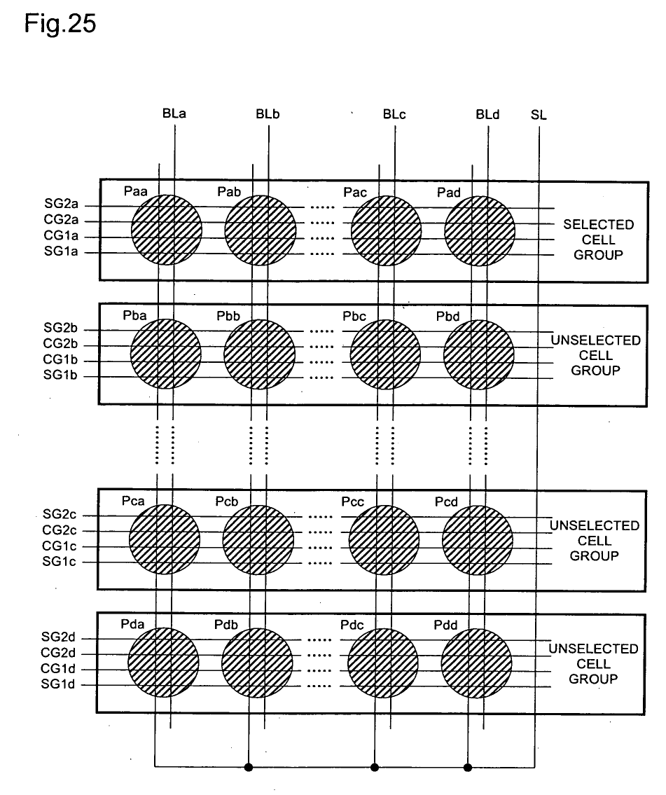

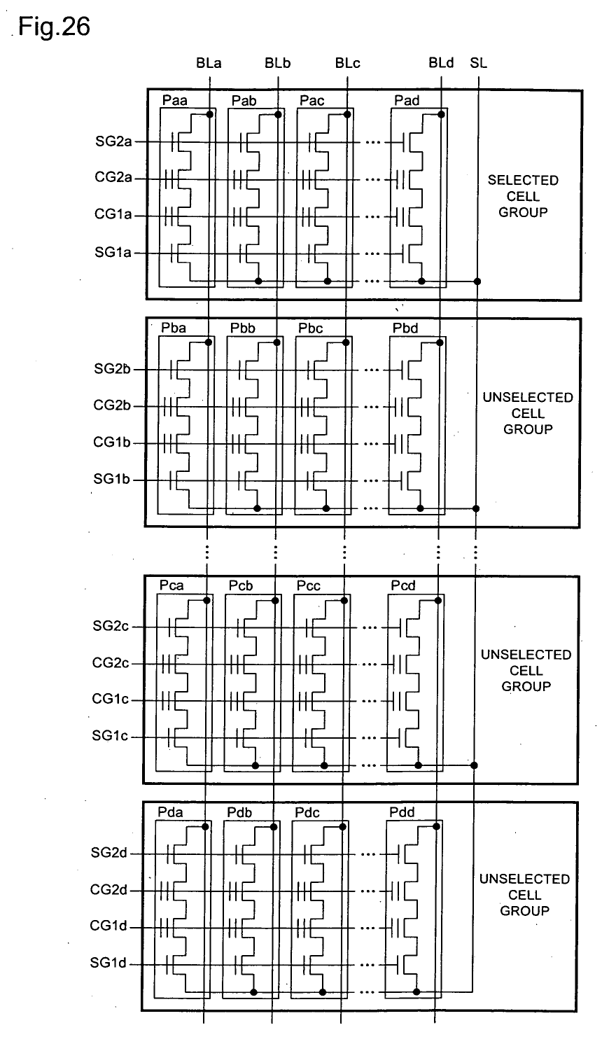

FIG. 25 is a block diagram illustrating a memory cell unit array including NAND memory cell units of FIG. 1 arranged in a matrix configuration. FIG. 26 is an equivalent circuit diagram of the memory cell unit array. As shown in FIGS. 25 and 26, there are NAND memory cell units Paa, Pab to Pac, Pad selected by selection gate lines SG1a, SG2a and control gate lines CG1a, CG2a, NADN memory cell units Pba, Pbb to Pbc, Pbd selected by selection gate lines SG1b, SG2b and control gate lines CG1b, CG2b, NAND memory cell units Pca, Pcb to Pcc, Pcd selected by selection gate lines SG1c, SG2c and control gate lines CG1c, CG2c, and NAND memory cell units selected by selection gate lines SG1d, SG2d and control gate lines CG1d, CG2d. Further, there are provided bit lines BLa to BLd and a common source line SL crossing the selection gate lines and the control gate lines. An explanation will hereinafter be given to writing operations to be performed on a memory cell of the nonvolatile semiconductor device and the breakdown voltages of the selection transistors.

First Writing Operation (Where Source Potential is at Ground Level GND)

In the memory cell unit array shown in FIG. 25, the selection gate lines SG1a, SG2a and the control gate lines CG1a, CG2a are selected, and the other selection gate lines SG1b, SG2b, SG1c, SG2c, SG1d, SG2d and the other control gate lines CG1b, CG2b, CG1c, CG2c, CG1d, CG2d are unselected. Where a writing operation is performed on a lower memory cell M1 of any one of the selected memory cell units Paa, Pab to Pac, Pad, a high voltage VH1 is applied to the control gate line CG1a (control gate 2), and a voltage VH2 (VH2<VH1) such as to prevent the writing is applied to the control gate line CG2a (control gate 4). A positive voltage VH3 is applied to the selection gate line SG2a (selection gate 6), and the selection gate line SG1a (selection gate 5) and the source line SL (source terminal 11) are grounded.

A bit line (drain terminal 7) of the memory cell to be subjected to electron injection out of the cells connected to the control gate line CG1a is grounded, whereby the N-type diffusion layers 8, 9, 10 are kept at a grounding potential. Then, the floating channel is at the grounding potential, so that the high voltage VH1 occurs between the control gate line CG1a (control gate 2) and the floating channel. At this time, electrons are injected into the charge storage layer 1 from the floating channel by a tunnel current. The threshold voltage of the memory cell M1 is positively shifted by the electron injection. On the other hand, a voltage between the control gate line CG2a (control gate 4) and the floating channel of the memory cell M2 is kept at the voltage VH2 (VH2<VH1) such as to prevent the writing. Hence, the writing to the memory cell M2 is prevented with the threshold voltage of the memory cell M2 unchanged.

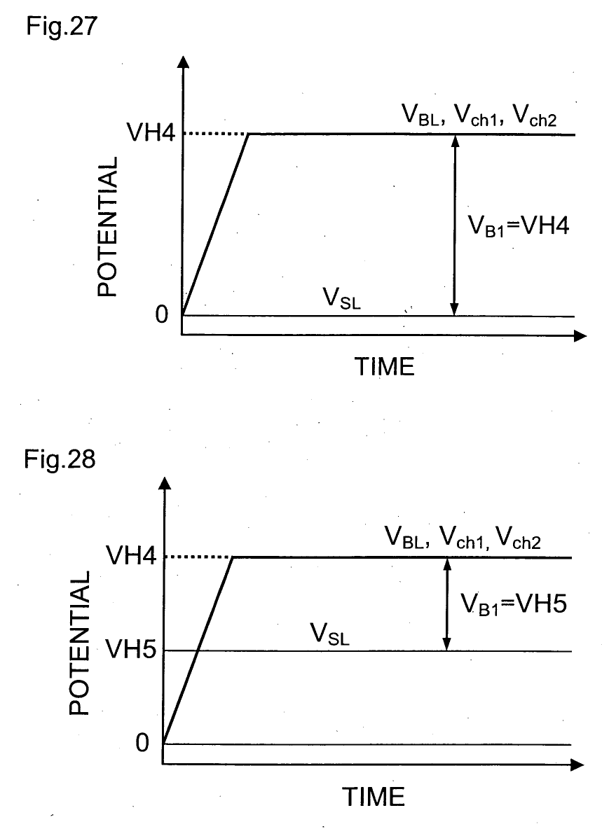

The writing to the memory cells not subjected to the electron injection out of the cells connected to the control gate line CG1a is prevented by applying a writing prevention voltage VH4 to the corresponding bit lines. FIG. 27 is a graph illustrating changes in the channel potentials Vch1, Vch2 of the memory cells M1, M2 observed with time when the bit line writing prevention voltage VH4 is applied to the bit lines. Here, the voltage application to the bit lines follows the voltage application to the selection gate line SG2a and the control gate lines CG1a, CG2a. Whether the voltage application to the bit lines follows or precedes the voltage application to the selection gate line SG2a and the control gate lines CG1a, CG2a, the channel potential Vch1 is increased to the writing prevention voltage VH4. At this time, a potential difference which is equivalent to a difference between the writing prevention voltage VH4 and the grounding potential occurs between the source (source terminal 11) and the drain (N-type diffusion layer 10) of the selection transistor N1. Since the breakdown voltage VB1 of the selection transistor N1 is not lower than a level equivalent to a difference between the bit line writing prevention voltage VH4 and the source line voltage, i.e., not lower than the bit line writing prevention voltage VH4, the potential of the N-type diffusion layer 11 and the floating channel potential Vch1 are kept at the bit line writing prevention voltage VH4. Therefore, a voltage between the control gate line CG1a (control gate 2) and the floating channel is kept at a level equivalent to a difference between the high voltage VH1 and the bit line writing prevention voltage VH4. Hence, erroneous electron injection to the charge storage layer 1 is prevented.

Where the writing operation is performed on an upper memory cell M2 of any one of the selected memory cell units Paa, Pab to Pac, Pad, a high voltage VH1 is applied to the control gate line CG2a (control gate 4), and a voltage VH2 (VH2<VH1) such as to prevent the writing is applied to the control gate line CG1a (control gate 2). A positive voltage VH3 is applied to the selection gate line SG2a (selection gate 6), and the selection gate line SG1a (selection gate 5) and the source line SL (source terminal 11) are grounded. A bit line (drain terminal 7) of the memory cell to be subjected to the electron injection out of the cells connected to the control gate line CG2a is grounded, whereby the N-type diffusion layers 8, 9, 10 are kept at a grounding potential. Then, the floating channel is at the grounding potential, so that the high voltage VH1 occurs between the control gate line CG2a (control gate 4) and the floating channel. At this time, electrons are injected into the charge storage layer 3 from the floating channel by a tunnel current. The threshold voltage of the memory cell M2 is positively shifted by the electron injection. On the other hand, a voltage between the control gate line CG1a (control gate 2) and the floating channel of the memory cell M1 is kept at the voltage VH2 (VH2<VH1) such as to prevent the writing. Hence, the writing to the memory cell M1 is prevented with the threshold voltage of the memory cell M1 unchanged.

The writing to the memory cells not subjected to the electron injection out of the cells connected to the control gate line CG2a is prevented by applying the writing prevention voltage VH4 to the corresponding bit lines. When the bit line writing prevention voltage VH4 is applied to the bit lines, the channel potentials Vch1, Vch2 of the memory cells M1, M2 change with time as shown in FIG. 27. The channel potential Vch2 is increased to the writing prevention voltage VH4. At this time, a potential difference which is equivalent to the difference between the writing prevention voltage VH4 and the grounding potential occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage, i.e., not lower than the bit line writing prevention voltage VH4, the potential of the N-type diffusion layer 11 and the floating channel potentials Vch1, Vch2 of the memory cells M1, M2 are kept at the bit line writing prevention voltage VH4. Therefore, a voltage between the control gate line CG2a (control gate 4) and the floating channel is kept at the level equivalent to the difference between the high voltage VH1 and the bit line writing prevention voltage VH4. Hence, erroneous electron injection to the charge storage layer 3 is prevented.

Second Writing Operation (Where Source Potential is at Positive Level)

Where a writing operation is performed on a lower memory cell M1 of any one of the selected memory cell units Paa, Pab to Pac, Pad in the memory cell array shown in FIG. 25, a high voltage VH1 is applied to the control gate line CG1a (control gate 2), and a voltage VH2 (VH2<VH1) such as to prevent the writing is applied to the control gate line CG2a (control gate 4). A positive voltage VH3 is applied to the selection gate line SG2a (selection gate 6), and a positive voltage is applied to the source line SL (source terminal 11). Further, the selection gate line SG1a (selection gate 5) is kept at a grounding potential. Here, the positive voltage to be applied to the source line SL (source terminal 11) is a voltage VH5 which is one half a bit line writing prevention voltage VH4. A bit line (drain terminal 7) of the memory cell to be subjected to electron injection out of the cells connected to the control gate line CG1a is grounded, whereby the N-type diffusion layers 8, 9, 10 are kept at the grounding potential. Then, the floating channel is at the grounding potential, so that the high voltage VH1 occurs between the control gate line CG1a (control gate 2) and the floating channel. At this time, a potential difference which is equivalent to a difference VH5 between the source line voltage VH5 and the grounding potential occurs between the source (source terminal 11) and the drain (N-type diffusion layer 10) of the selection transistor N1. Since the breakdown voltage VB1 of the selection transistor N1 is not lower than a level equivalent to a difference between the bit line writing prevention voltage VH4 and the source line voltage VH5, i.e., not lower than the source line voltage VH5, the potential of the N-type diffusion layer 11 and the floating channel potential Vch1 are kept at the grounding potential. Therefore, electrons are injected into the charge storage layer 1 from the floating channel by a tunnel current. The threshold voltage of the memory cell M1 is positively shifted by the electron injection. On the other hand, a voltage between the control gate line CG2a (control gate 4) and the floating channel of the memory cell M2 is kept at the voltage VH2 (VH2<VH1) such as to prevent the writing. Hence, the writing to the memory cell M2 is prevented with the threshold voltage of the memory cell M2 unchanged.

On the other hand, the writing to the memory cells not subjected to the electron injection out of the cells connected to the control gate line CG1a is prevented by applying the writing prevention voltage VH4 to the corresponding bit lines. FIG. 28 is a graph illustrating changes in the channel potentials Vch1, Vch2 of the memory cells M1, M2 observed with time when the bit line writing prevention voltage VH4 is applied to the bit lines. Here, the voltage application to the bit lines follows the voltage application to the selection gate line SG2a and the control gate lines CG1a, CG2a. Whether the voltage application to the bit lines follows or precedes the voltage application to the selection gate line SG2a and the control gate lines CG1a, CG2a, the channel potential Vch1 is increased to the writing prevention voltage VH4. At this time, a potential difference which is equivalent to the difference VH5 between the writing prevention voltage VH4 and the source line voltage VH5 occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage VH5, i.e., not lower than the source line voltage VH5, the potential of the N-type diffusion layer 11 and the floating channel potential Vch1 are kept at the bit line writing prevention voltage VH4. Therefore, a voltage between the control gate line CG1a (control gate 2) and the floating channel is kept at a level equivalent to a difference between the high voltage VH1 and the writing prevention voltage VH4. Hence, electrons are not injected into the charge storage layer 1.

Where the writing operation is performed on an upper memory cell M2 of any one of the selected memory cell units Paa, Pab to Pac, Pad, a high voltage VH1 is applied to the control gate line CG2a (control gate 4), and a voltage VH2 (VH2<VH1) such as to prevent the writing is applied to the control gate line CG1a (control gate 2). A positive voltage VH3 is applied to the selection gate line SG2a (selection gate 6), and the selection gate line SG1a (selection gate 5) is kept at a grounding potential. Further, a positive voltage is applied to the source line SL (source terminal 11). Here, the positive voltage to be applied to the source line SL (source terminal 11) is a voltage VH5 which is one half a bit line writing prevention voltage VH4. A bit line (drain terminal 7) of the memory cell to be subjected to the electron injection out of the cells connected to the control gate line CG2a is grounded, whereby the N-type diffusion layers 8, 9, 10 are kept at the grounding potential. Then, the floating channel is at the grounding potential, so that the high voltage VH1 occurs between the control gate line CG2a (control gate 4) and the floating channel. At this time, electrons are injected into the charge storage layer 3 from the floating channel by a tunnel current. The threshold voltage of the memory cell M2 is positively shifted by the electron injection. On the other hand, a voltage between the control gate line CG1a (control gate 2) and the floating channel of the memory cell M1 is kept at the voltage VH2 (VH2<VH1) such as to prevent the writing.

Therefore, the writing to the memory cell M1 is prevented with the threshold voltage of the memory cell M1 unchanged. At this time, a potential difference which is equivalent to the difference VH5 between the source line voltage VH5 and the grounding potential occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage VH5, i.e., not lower than the source line voltage VH5, the potential of the N-type diffusion layer 11 and the potentials Vch1, Vch2 of the floating channels of the memory cells M1, M2 are kept at the grounding potential.

On the other hand, the writing to the memory cells not subjected to the electron injection out of the cells connected to the control gate line CG2a is prevented by applying the writing prevention voltage VH4 to the corresponding bit lines. When the bit line writing prevention voltage VH4 is applied to the bit lines, the channel potentials Vch1, Vch2 of the memory cells M1, M2 change with time as shown in FIG. 28, and the channel potential Vch2 is increased to the writing prevention voltage VH4. At this time, a potential difference which is equivalent to the difference VH5 between the writing prevention voltage VH4 and the source line voltage VH5 occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage VH5, i.e., not lower than the source line voltage VH5, the potential of the N-type diffusion layer 11 and the floating channel potentials Vch1 and Vch2 of the memory cells M1, M2 are kept at the bit line writing prevention voltage VH4. Therefore, a voltage between the control gate line CG2a (control gate 4) and the floating channel is kept at a level which is equivalent to the difference between the high voltage VH1 and the bit line writing prevention voltage VH4. Hence, the electron injection to the charge storage layer 3 is prevented.

Third Embodiment

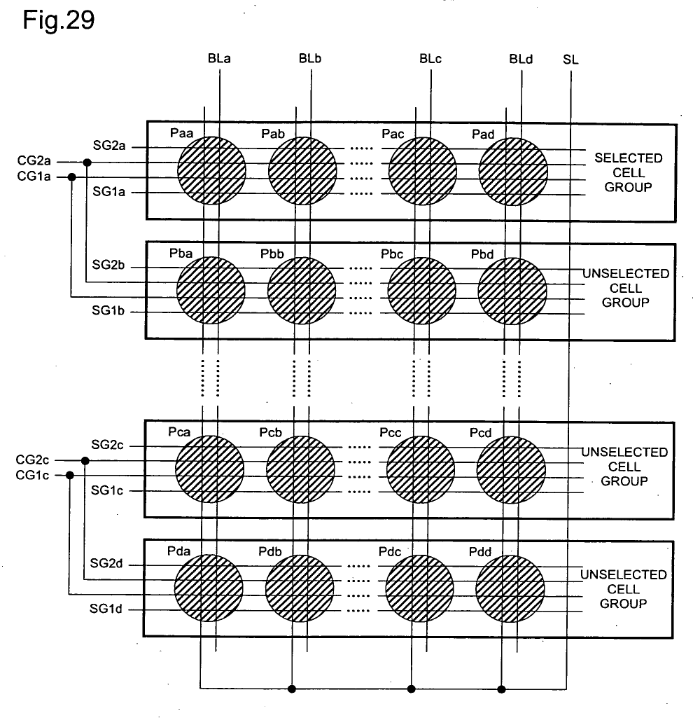

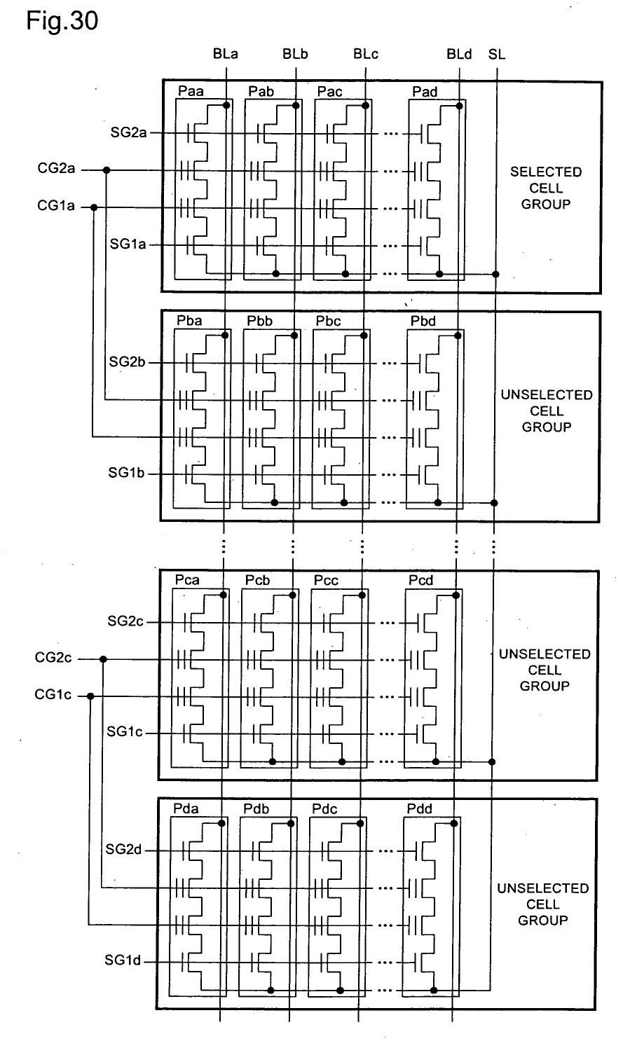

FIG. 29 illustrates an exemplary memory cell unit array having substantially the same construction as the memory cell unit array shown in FIG. 25 but having a plurality of control gate lines shared by memory cells in different memory cell unit groups. FIG. 30 is an equivalent circuit diagram of the memory cell unit array. In the memory cell unit array shown in FIG. 25, one control gate selector transistor should be provided for each row of column-shaped semiconductor layers arranged along a control gate line in a space having a width as measured along a bit line for the row of column-shaped semiconductor layers. On the other hand, the memory cell unit array shown in FIG. 29 is advantageous in that an interconnection routing pitch of control gate lines is increased by connecting each two control gate lines to one common line and one control gate selector transistor is disposed in a space having a width as measured along a bit line for two rows of column-shaped semiconductor layers. Here, an explanation will be given to a case where two control gate lines are shared by two different memory cell unit groups. This memory cell unit array includes NAND memory cell units Paa, Pab to Pac, Pad selected by selection gate lines SG1a, SG2a and control gate lines CG1a, CG2a, NAND memory cell units Pba, Pbb to Pbc, Pbd selected by selection gate lines SG1b, SG2b and the control gate lines CG1a, CG2a, NAND memory cell units Pca, Pcb to Pcc, Pcd selected by selection gate lines SG1c, SG2c and control gate lines CG1c, CG2c, and NAND memory cell units selected by selection gate lines SG1d, SG2d and the control gate lines CG1c, CG2c. Further, there are provided bit lines BLa to BLd and a common source line SL crossing the selection gate lines and the control gate lines. In a memory cell unit provided in the memory cell unit array according to this embodiment, as shown in FIG. 1, a column-shaped semiconductor layer may be electrically isolated from a semiconductor substrate by an impurity diffusion layer having a conductivity opposite to the conductivity of the semiconductor substrate, by a depletion layer to be formed in a junction between an impurity diffusion layer and the semiconductor substrate or the column-shaped semiconductor layer, or by an insulation film such as of SiO₂. An explanation will hereinafter be given to writing operations to be performed on a memory cell.

Third Writing Operation (Where Control Gate Lines are Shared and Source Potential is at Ground Level GND)

In the memory cell unit array shown in FIG. 29, the selection gate lines SG1a, SG2a and the common control gate lines CG1a, CG2a are selected, and the other selection gate lines SG2b, SG1c, SG2c, SG1d, SG2d and the other common control gate lines CG1c, CG2c are unselected. Where a writing operation is performed on a lower memory cell M1 of any one of the selected memory cell units Paa, Pab to Pac, Pad, a high voltage VH1 is applied to the common control gate line CG1a (control gate 2), and a voltage VH2 (VH2<VH1) such as to prevent the writing is applied to the common control gate line CG2a (control gate 4). A positive voltage VH3 is applied to the selection gate line SG2a (selection gate 6), and the selection gate line SG1a (selection gate 5), the source line SL (source terminal 11) and the selection gate line SG1b of the memory cell units Pba, Pbb to Pbc, Pbd connected to the common control gate line CG1a are grounded.

A bit line (drain terminal 7) of the memory cell to be subjected to electron injection out of the cells selected by the selection gate lines SG1a, SG2a and connected to the common control gate line CG1a is grounded, whereby the N-type diffusion layers 8, 9, 10 are kept at a grounding potential. Then, the floating channel is at the grounding potential, so that the high voltage VH1 occurs between the common control gate line CG1a (control gate 2) and the floating channel. At this time, electrons are injected into the charge storage layer 1 from the floating channel by a tunnel current. The threshold voltage of the memory cell M1 is positively shifted by the electron injection. On the other hand, a voltage between the control gate line CG1a (control gate 4) and the floating channel of the memory cell M2 is kept at the voltage VH2 (VH2<VH1) such as to prevent the writing. Hence, the writing to the memory cell M2 is prevented with the threshold voltage of the memory cell M2 unchanged.

On the other hand, the writing to the memory cells not subjected to the electron injection out of the cells selected by the selection gate lines SG1a, SG2a and connected to the common control gate line CG1a is prevented by applying a writing prevention voltage VH4 to the corresponding bit lines. With the application of the writing prevention voltage VH4, the channel potential Vch1 of each of the unselected cells is increased to a level equivalent to the writing prevention voltage VH4. At this time, a potential difference which is equivalent to a difference between the writing prevention voltage VH4 and the grounding potential occurs between the source (source terminal 11) and the drain (N-type diffusion layer 10) of the selection transistor N1. Since the breakdown voltage VB1 of the selection transistor N1 is not lower than a level equivalent to a difference between the bit line writing prevention voltage VH4 and the source line voltage, i.e., not lower than the bit line writing prevention voltage VH4, the potential of the N-type diffusion layer 11 and the floating channel potential Vch1 are kept at the bit line writing prevention voltage VH4. Therefore, a voltage between the common control gate line CG1a (control gate 4) and the floating channel is kept at a level equivalent to a difference between the high voltage VH1 and the bit line writing prevention voltage VH4. Hence, erroneous electron injection to the charge storage layer 1 is prevented.

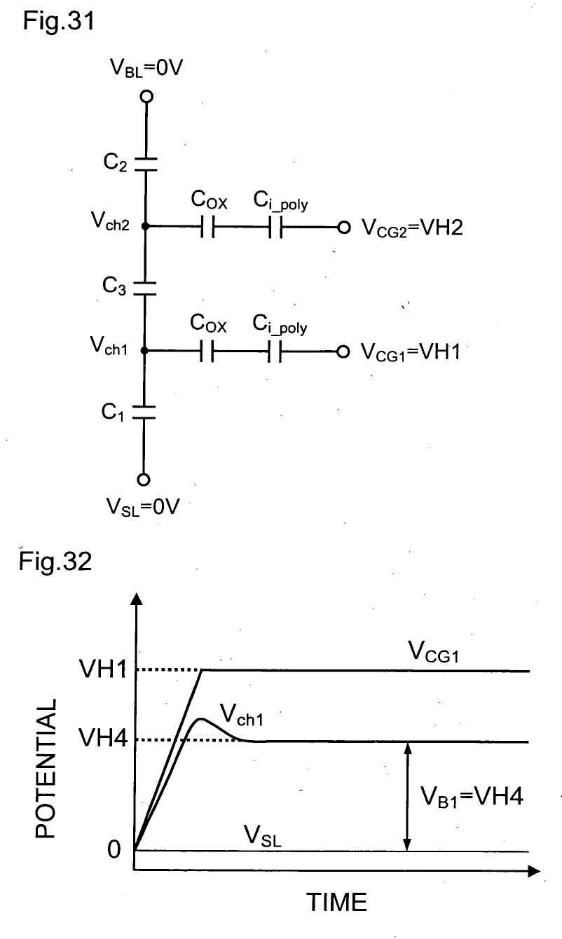

FIG. 31 is a circuit diagram illustrating a simplified capacitance network of each of the NAND memory cell units Pba, Pbb to Pbc, Pbd which share the common control gate lines CG1a, CG2a with the selected memory cell unit group. FIG. 32 is a graph illustrating a change in the channel potential Vch1 of the memory cell M1 with time. With the application of the high voltage VH1 to the common control gate line CG1a, the floating channel potential Vch1 of the memory cell M1 is increased by the coupling of a capacitance Ci_poly between the floating gate and the control gate line and a capacitance COX between the floating gate and the channel layer. Here, the bit lines are at the grounding potential. The channel potential Vch1 is also increased where the writing prevention voltage VH4 is applied to the bit lines. If a voltage not lower than the breakdown voltage VB1 of the selection transistor N1 is applied between the N-type diffusion layer 10 and the source line 11, the potential of the N-type diffusion layer and the floating channel potential Vch1 of the memory cell M1 are reduced to a level equivalent to the breakdown voltage. However, the breakdown voltage VB1 is not lower than the level equivalent to the difference between the bit line writing prevention voltage VH4 and the source line voltage, i.e., not lower than the bit line writing prevention voltage VH4, so that the floating channel potential Vch1 is not lower than the writing prevention voltage VH4. Therefore, the writing to the memory cell M1 is prevented.

Where the writing operation is performed on an upper memory cell M2 of any one of the memory cell units Paa, Pab to Pac, Pad, a high voltage VH1 is applied to the common control gate line CG2a (control gate 4), and a voltage VH2 (VH2<VH1) such as to prevent the writing is applied to the common control gate line CG1a (control gate 2). Further, a positive voltage VH3 is applied to the selection gate line SG2a (selection gate 6), and the selection gate line SG1a (selection gate 5) and the source line SL (source terminal 11) are grounded.

A bit line (drain terminal 7) of the memory cell to be subjected to the electron injection out of the cells selected by the selection gate lines SG1a, SG2a and connected to the common control gate line CG2a is grounded, whereby the N-type diffusion layers 8, 9, 10 are kept at a grounding potential. Then, the floating channel is at the grounding potential, so that the high voltage VH1 occurs between the common control gate line CG2a (control gate 4) and the floating channel. At this time, electrons are injected into the charge storage layer 3 from the floating channel by a tunnel current. The threshold voltage of the memory cell M2 is positively shifted by the electron injection. On the other hand, a voltage between the control gate line CG1a (control gate 2) and the floating channel of the memory cell M1 is kept at the voltage VH2 (VH2<VH1) such as to prevent the writing. Therefore, the writing to the memory cell M1 is prevented with the threshold voltage of the memory cell M1 unchanged.

The writing to the memory cells not subjected to the electron injection out of the cells selected by the selection gate lines SG1a, SG2a and connected to the common control gate line CG2a is prevented by applying the writing prevention voltage VH4 to the corresponding bit lines. With the application of the writing prevention voltage VH4, the channel potentials Vch2 of the unselected cells are increased to a level equivalent to the writing prevention voltage VH4. At this time, a potential difference which is equivalent to the difference between the writing prevention voltage VH4 and the grounding potential occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage, i.e., not lower than the bit line writing prevention voltage VH4, the potential of the N-type diffusion layer 11 and the floating channel potentials Vch1, Vch2 are kept at the bit line writing prevention voltage VH4. Therefore, a voltage between the common control gate line CG2a (control gate 4) and the floating channel is kept at the level equivalent to the difference between the high voltage VH1 and the bit line writing prevention voltage VH4. Hence, erroneous electron injection to the charge storage layer 3 is prevented.

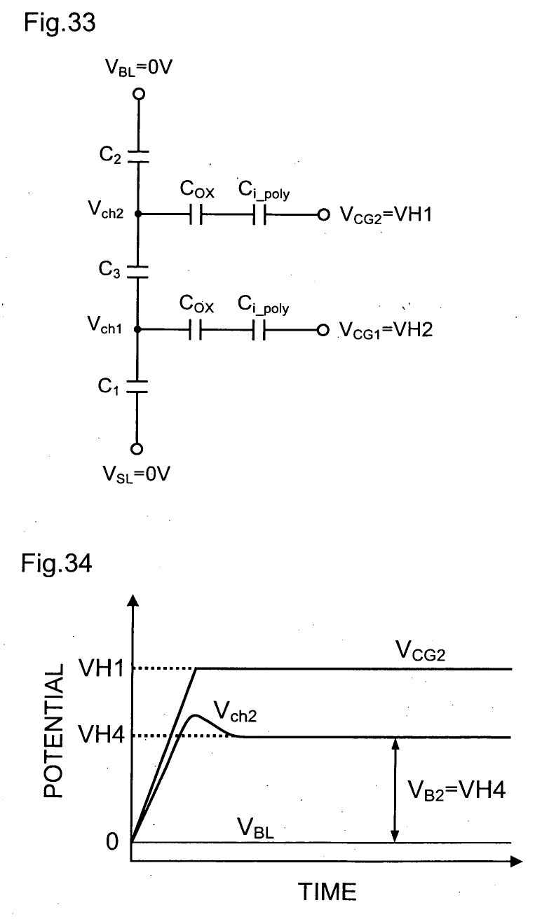

FIG. 33 is a circuit diagram illustrating a simplified capacitance network of each of the NAND memory cell units Pba, Pbb to Pbc, Pbd which share the common control gate lines CG1a, CG2a with the selected memory cell unit group. FIG. 34 is a graph illustrating a change in the channel potential Vch2 of the memory cell M2 with time. With the application of the high voltage VH1 to the control gate line CG2a, the floating channel potential Vch2 of the memory cell M2 is increased by the coupling of a capacitance Ci_poly between the floating gate and the control gate line and a capacitance COX between the floating gate and the channel layer. If a voltage not lower than the breakdown voltage VB2 of the selection transistor N2 is applied between the bit line 7 and the N-type diffusion layer 8, the potential of the N-type diffusion layer and the floating channel potential Vch2 of the memory cell M2 are reduced to a level equivalent to the breakdown voltage. However, the breakdown voltage VB2 is not lower than the bit line writing prevention voltage VH4, so that the floating channel potential Vch2 is not lower than the writing prevention voltage VH4. Therefore, the writing to the memory cell M2 is prevented.

Fourth Writing Operation (Where Control Gate Lines are Shared and Source Potential is at Positive Level)

Where a writing operation is performed on a lower memory cell M1 of any one of the memory cell units Paa, Pab to Pac, Pad in the memory cell unit array shown in FIG. 29, a high voltage VH1 is applied to the common control gate line CG1a (control gate 2), and a voltage VH2 (VH2<VH1) such as to prevent the writing is applied to the common control gate line CG2a (control gate 4). A positive voltage VH3 is applied to the selection gate line SG2a (selection gate 6), and a positive voltage is applied to the source line SL (source terminal 11) and the selection gate line SG1b of the memory cell units Pba, Pbb to Pbc, Pbd connected to the common control gate line CG1a. Further, the selection gate line SG1a (selection gate 5) is grounded. Here, the positive voltage to be applied to the selection gate line SG1b (selection gate 5) and the source line SL (source terminal 11) is a voltage VH5 which is one half a bit line writing prevention voltage VH4.

A bit line (drain terminal 7) of the memory cell to be subjected to electron injection out of the cells selected by the selection gate lines SG1a, SG2a and connected to the common control gate line CG1a is grounded, whereby the N-type diffusion layers 8, 9, 10 are kept at a grounding potential. Then, the floating channel is at the grounding potential, so that the high voltage VH1 occurs between the common control gate line CG1a (control gate 2) and the floating channel. At this time, a potential difference which is equivalent to a difference VH5 between the source line voltage VH5 and the grounding potential occurs between the source (source terminal 11) and the drain (N-type diffusion layer 10) of the selection transistor N1. Since the breakdown voltage VB1 of the selection transistor N1 is not lower than a level equivalent to a difference between the bit line writing prevention voltage VH4 and the source line voltage VH5, i.e., not lower than the source line voltage VH5, the potential of the N-type diffusion layer 11 and the floating channel potential Vch1 are kept at the grounding potential. Therefore, electrons are injected into the charge storage layer 1 from the floating channel by a tunnel current. The threshold voltage of the memory cell M1 is positively shifted by the electron injection.

On the other hand, a voltage between the control gate line CG1a (control gate 4) and the floating channel of the memory cell M2 is kept at the voltage VH2 (VH2<VH1) such as to prevent the writing, so that the writing to the memory cell M2 is prevented with the threshold voltage of the memory cell M2 unchanged.

The writing to the memory cells not subjected to the electron injection out of the cells selected by the selection gate lines SG1a, SG2a and connected to the common control gate line CG1a is prevented by applying the writing prevention voltage VH4 to the corresponding bit lines. With the application of the writing prevention voltage VH4, the channel potential Vch1 is increased to a level equivalent to the writing prevention voltage VH4. At this time, a potential difference which is equivalent to the difference VH5 between the writing prevention voltage VH4 and the source line voltage VH5 occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage VH5, i.e., not lower than the source line voltage VH5, the potential of the N-type diffusion layer 11 and the floating channel potential Vch1 are kept at the bit line writing prevention voltage VH4. Therefore, a voltage between the common control gate line CG1a (control gate 4) and the floating channel is kept at a level equivalent to a difference between the high voltage VH1 and the bit line writing prevention voltage VH4. Hence, the electron injection to the charge storage layer 1 is prevented.

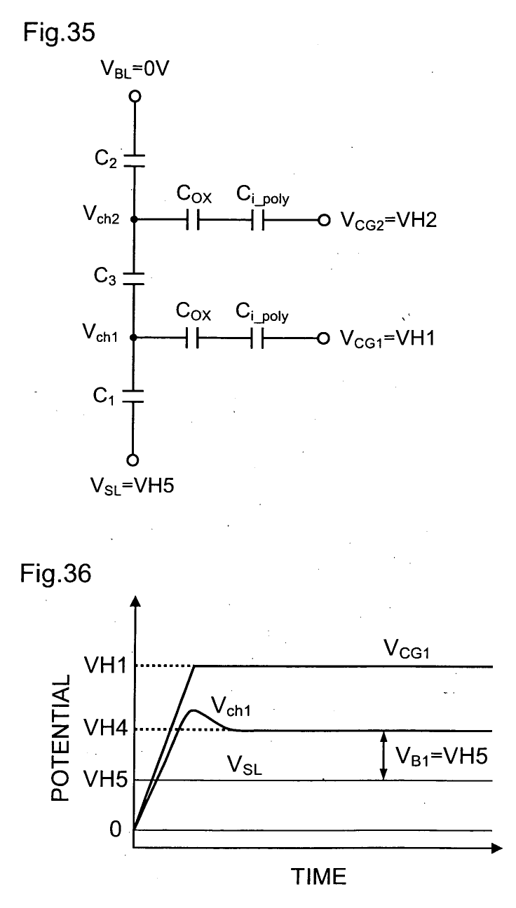

FIG. 35 is a circuit diagram illustrating a simplified capacitance network of each of the NAND memory cell units Pba, Pbb to Pbc, Pbd which share the common control gate lines CG1a, CG2a with the selected memory cell unit group. FIG. 36 is a graph illustrating a change in the channel potential Vch1 of the memory cell M1 with time. With the application of the high voltage VH1 to the control gate line CG1a, the floating channel potential Vch1 of the memory cell M1 is increased by the coupling of a capacitance Ci_poly between the floating gate and the control gate line and a capacitance COX between the floating gate and the channel layer. Here, the bit lines are at the grounding potential. Where the writing prevention voltage is applied to the bit lines, the channel potential Vch1 is also increased. If a voltage not lower than the breakdown voltage VB1 of the selection transistor N1 is applied between the N-type diffusion layer 10 and the source line 11, the potential of the N-type diffusion layer and the floating channel potential Vch1 of the memory cell M1 are reduced to a level equivalent to the breakdown voltage. However, the breakdown voltage VB1 of the selection transistor N1 is not lower than the level equivalent to the difference between the bit line writing prevention voltage VH4 and the source line voltage, i.e., not lower than the source line voltage VH5, so that the floating channel potential Vch1 is not lower than the writing prevention voltage VH4. Therefore, erroneous writing to the memory cell M1 is prevented.

Where the writing operation is performed on an upper memory cell M2 of any one of the memory cell units Paa, Pab to Pac, Pad, a high voltage VH1 is applied to the common control gate line CG2a (control gate 4), and a voltage VH2 (VH2<VH1) such as to prevent the writing is applied to the common control gate line CG1a (control gate 2). A positive voltage VH3 is applied to the selection gate line SG2a (selection gate 6), and a positive voltage VH5 is applied to the source line SL (source terminal 11). Further, the selection gate line SG1a (selection gate 5) is kept at a grounding potential. A bit line (drain terminal 7) of the memory cell to be subjected to the electron injection out of the cells selected by the selection gate lines SG1a, SG2a and connected to the common control gate line CG2a is grounded, whereby the N-type diffusion layers 8, 9, 10 are kept at the grounding potential. Then, the floating channel is at the grounding potential, so that the high voltage VH1 occurs between the common control gate line CG2a (control gate 4) and the floating channel. At this time, electrons are injected into the charge storage layer 3 from the floating channel by a tunnel current. The threshold voltage of the memory cell M2 is positively shifted by the electron injection. On the other hand, a voltage between the control gate line CG1a (control gate 2) and the floating channel of the memory cell M1 is kept at the voltage VH2 (VH2<VH1) such as to prevent the writing. Therefore, the writing to the memory cell M1 is prevented with the threshold voltage of the memory cell M1 unchanged.

The writing to the memory cells not subjected to the electron injection out of the cells selected by the selection gate lines SG1a, SG2a and connected to the common control gate line CG2a is prevented by applying the writing prevention voltage VH4 to the corresponding bit lines. With the application of the writing prevention voltage VH4, the channel potential Vch2 of each of the unselected cells is increased to a level equivalent to the writing prevention voltage VH4. At this time, a potential difference which is equivalent to a difference VH5 between the writing prevention voltage VH4 and the source line voltage VH5 occurs between the source (source terminal 11) and the drain (N-type diffusion layer 10) of the selection transistor N1. Since the breakdown voltage VB1 of the selection transistor N1 is not lower than the level equivalent to the difference between the bit line writing prevention voltage VH4 and the source line voltage VH5, i.e., not lower than the source line voltage VH5, the potential of the N-type diffusion layer 11 and the floating channel potentials Vch1 and Vch2 are kept at the bit line writing prevention voltage VH4. Therefore, a voltage between the common control gate line CG2a (control gate 4) and the floating channel is kept at the level equivalent to the difference between the high voltage VH1 and the bit line writing prevention voltage VH4. Hence, the electron injection to the charge storage layer 3 is prevented.

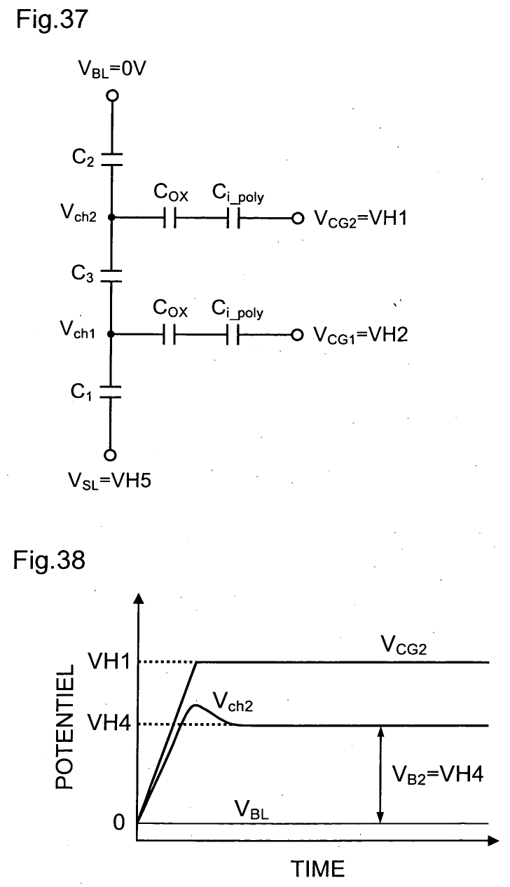

FIG. 37 is a circuit diagram illustrating a simplified capacitance network of each of the NAND memory cell units Pba, Pbb to Pbc, Pbd which share the common control gate lines CG1a, CG2a with the selected memory cell unit group and are connected to the unselected selection gate lines SG1b, SG2b. FIG. 38 is a graph illustrating a change in the channel potential Vch2 of the memory cell M2 with time. With the application of the high voltage VH1 to the control gate line CG2a, the floating channel potential Vch2 of the memory cell M2 is increased by the coupling of a capacitance Ci_poly between the floating gate and the control gate line and a capacitance COX between the floating gate and the channel layer. If a voltage not lower than the breakdown voltage VB2 of the selection transistor N2 is applied between the drain diffusion layer 7 and the N-type diffusion layer 8, the potential of the N-type diffusion layer and the floating channel potential Vch2 of the memory cell M2 are reduced to a level equivalent to the breakdown voltage. However, the breakdown voltage VB2 is not lower than the bit line writing prevention voltage VH4, so that the floating channel potential Vch2 is not lower than the writing prevention voltage VH4. Therefore, erroneous writing to the memory cell M2 is prevented.

Fourth Embodiment

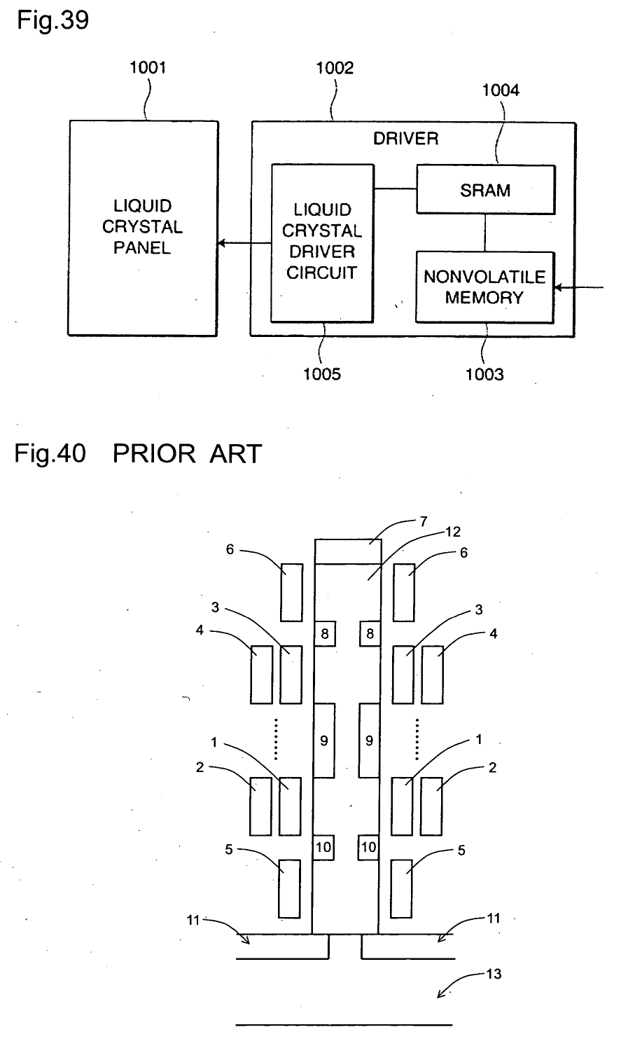

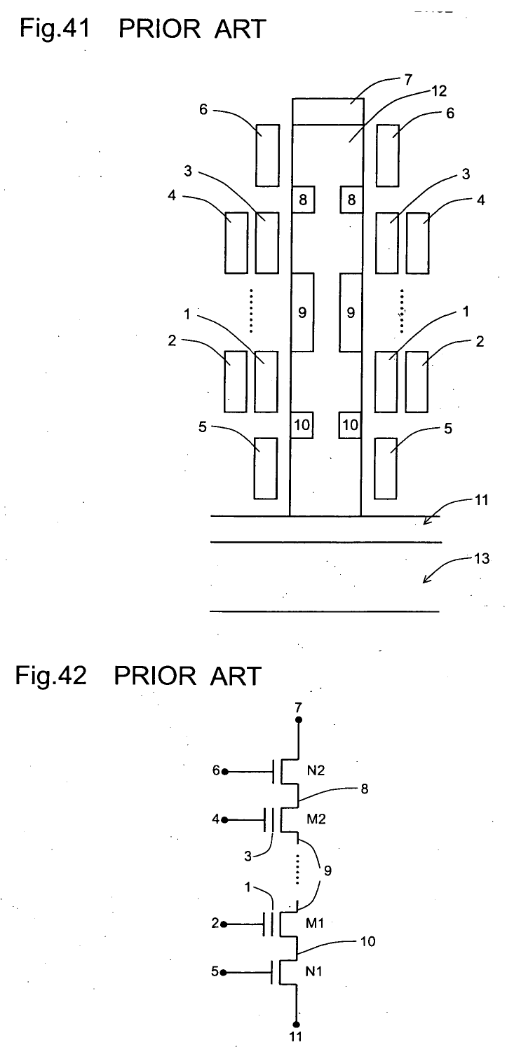

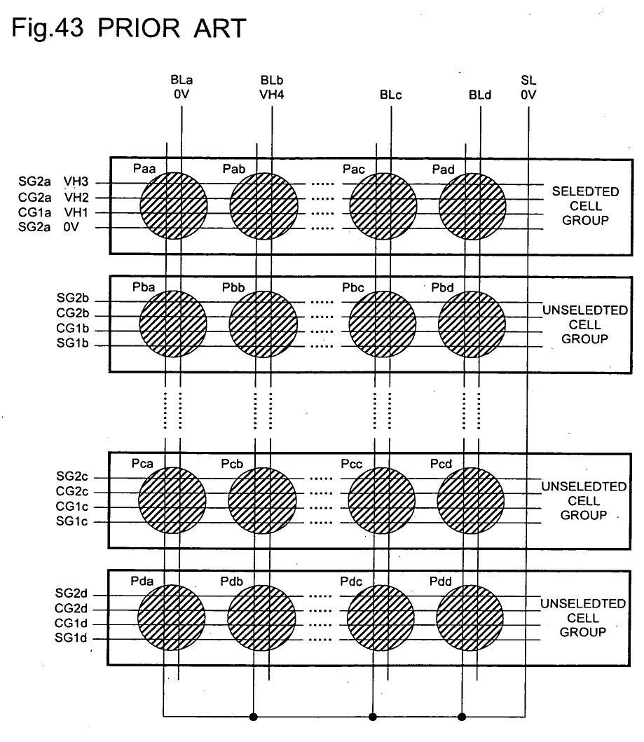

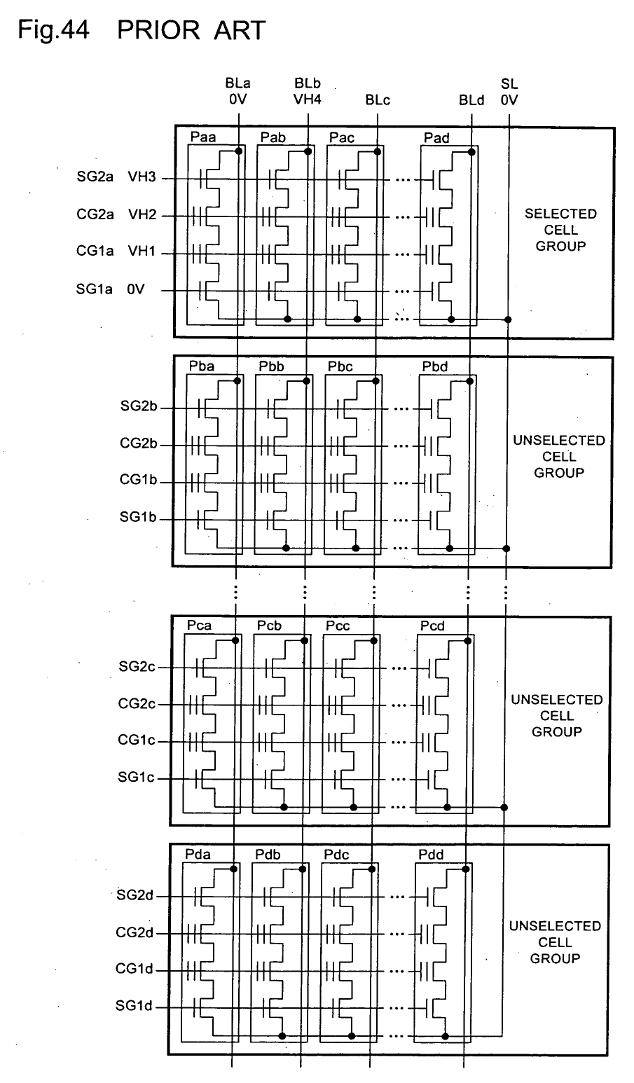

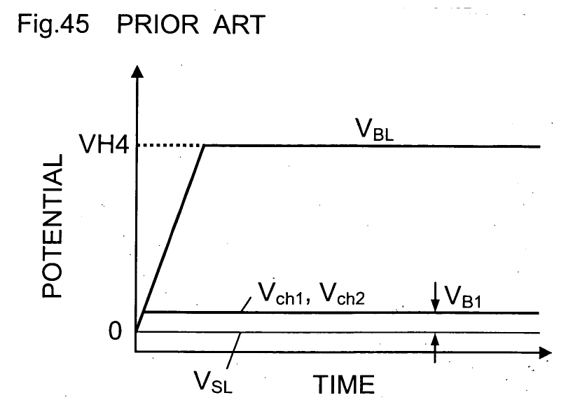

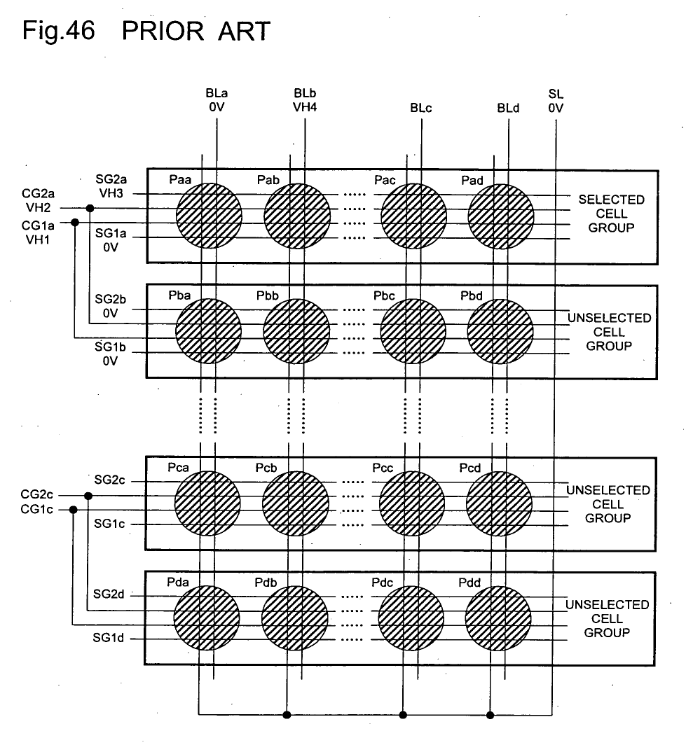

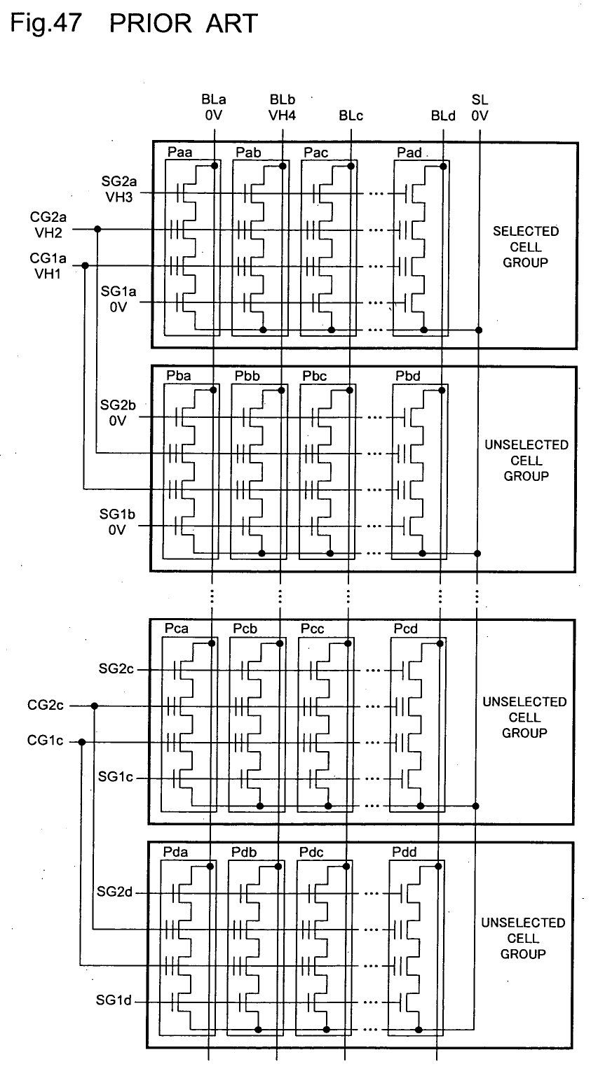

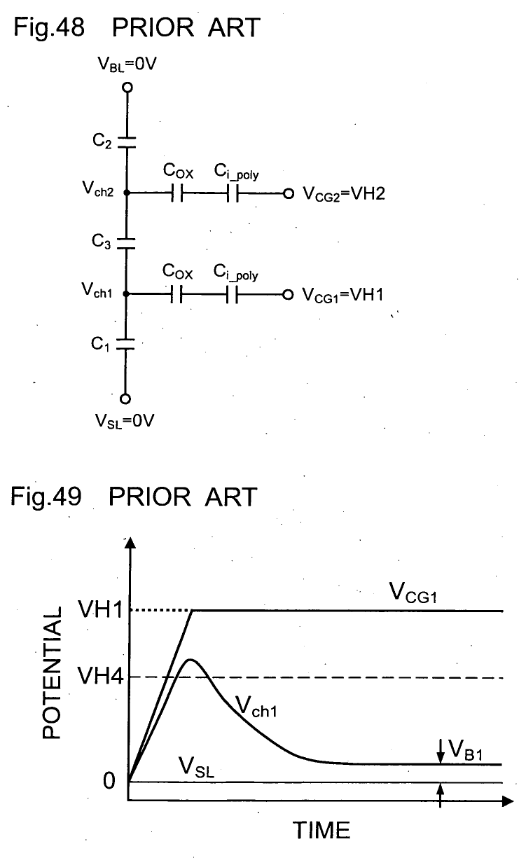

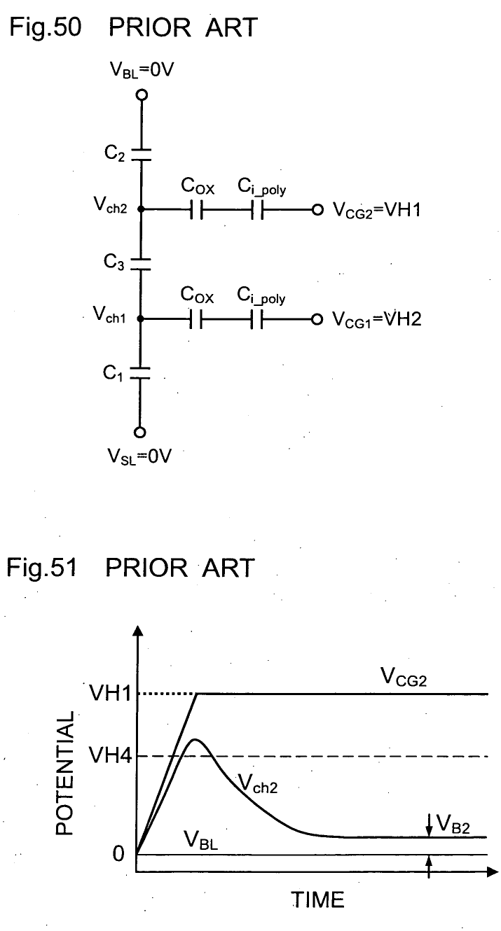

The semiconductor storage devices described above are applicable to a rewritable nonvolatile memory for image adjustment in a liquid crystal panel of a liquid crystal display device as shown in FIG. 39.

The liquid crystal panel 1001 is driven by a liquid crystal driver 1002. The liquid crystal driver 1002 includes a nonvolatile memory section 1003, an SRAM section 1004 and a liquid crystal driver circuit 1005 provided therein. The nonvolatile memory section 1003 comprises any of the inventive nonvolatile storage devices, preferably the semiconductor storage device according to the second embodiment. The nonvolatile memory section 1003 is configured so as to be rewritable from the outside.

Information stored in the nonvolatile memory section 1003 is transferred to the SRAM section 1004 when the liquid crystal display device is turned on. The liquid crystal driver circuit 1005 is capable of reading the information out of the SRAM section 1004 as required. The provision of the SRAM section 1004 makes it possible to read out the information at a very high speed.

The liquid crystal driver 1002 is provided outside the liquid crystal panel 1001 as shown in FIG. 39, but may be provided on the liquid crystal panel 1001.

The liquid crystal panel 1001 is adapted to change the tones of pixels thereof by applying a multi-level voltage to each of the pixels. However, a relationship between the applied voltage and the tone varies from panel to panel. Therefore, information for compensation for the panel-to-panel variation is stored after the production of the liquid crystal panel, and a panel-to-panel variation in image quality is eliminated by the compensation based on the information. Therefore, it is preferred to incorporate the rewritable nonvolatile memory for storing the information for the compensation. Further, it is preferred to employ the inventive semiconductor storage device as the nonvolatile memory. With the use of the inventive semiconductor storage device, erroneous writing to the semiconductor device can assuredly be prevented. This makes it possible to provide a liquid crystal display device which is highly reliable and stably operable.

1. A memory cell unit comprising:
a semiconductor substrate having a source diffusion layer provided in a surface thereof;
a column-shaped semiconductor layer provided on the source diffusion layer and having a drain diffusion layer provided in an uppermost portion thereof;
a memory cell arrangement which includes a plurality of memory cells arranged in series with the intervention of a first impurity diffusion layer on the column-shaped semiconductor layer perpendicularly to the substrate, the memory cells each having a charge storage layer and a control gate;
a first selection transistor connected to one end of the memory cell arrangement with the intervention of a second impurity diffusion layer and connected to the drain diffusion layer; and
a second selection transistor connected to the other end of the memory cell arrangement with the intervention of a third impurity diffusion layer and connected to the source diffusion layer;
wherein a distance between the third impurity diffusion layer and the source diffusion layer is greater than a distance between impurity diffusion layers disposed on opposite sides of each of the memory cells, whereby punch-through of the second selection transistor is prevented when a writing prevention voltage is applied between the source diffusion layer and the first impurity diffusion layer.

2. A memory cell unit of claim 1, wherein a distance between the drain diffusion layer and the second impurity diffusion layer is greater than the distance between the impurity diffusion layers disposed on the opposite sides of each of the memory cells, whereby punch-through of the first selection transistor is prevented when the writing prevention voltage is applied between the drain diffusion layer and the second impurity diffusion layer.

3. A nonvolatile semiconductor device comprising a plurality of memory cell units arranged longitudinally and transversely in a matrix configuration, wherein the memory cell units each comprise a memory cell unit as recited in claim 1.

4. A nonvolatile semiconductor device of claim 3,
wherein a plurality of control gate lines are each provided by sequentially connecting control gates of memory cells provided in column-shaped semiconductor layers arranged longitudinally in each column of the matrix configuration, and are commonly connected,
wherein a plurality of bit lines are each provided by connecting drain diffusion layers provided in column-shaped semiconductor layers arranged transversely in each row of the matrix configuration.

5. A liquid crystal display device comprising a nonvolatile semiconductor device as recited in claim 3.

6. A memory cell unit comprising:
a semiconductor substrate having a source diffusion layer provided in a part of a surface thereof;
a column-shaped semiconductor layer provided on the semiconductor substrate with a part of a bottom thereof being in contact with the source diffusion layer and with the other part of the bottom thereof being electrically connected to the semiconductor substrate, and having a drain diffusion layer provided in an uppermost portion thereof;
a memory cell arrangement which includes a plurality of memory cells arranged in series with the intervention of a first impurity diffusion layer on the column-shaped semiconductor layer perpendicularly to the substrate, the memory cells each having a charge storage layer and a control gate;
a first selection transistor connected to one end of the memory cell arrangement with the intervention of a second impurity diffusion layer and connected to the drain diffusion layer; and
a second selection transistor connected to the other end of the memory cell arrangement with the intervention of a third impurity diffusion layer and connected to the source diffusion layer;
wherein a distance between the third impurity diffusion layer and the source diffusion layer is greater than a distance between impurity diffusion layers disposed on opposite sides of each of the memory cells, whereby punch-through of the second selection transistor is prevented when a writing prevention voltage is applied between the source diffusion layer and the first impurity diffusion layer.

7. A memory cell unit of claim 6, wherein a distance between the drain diffusion layer and the second impurity diffusion layer is greater than the distance between the impurity diffusion layers disposed on the opposite sides of each of the memory cells, whereby punch-through of the first selection transistor is prevented when the writing prevention voltage is applied between the drain diffusion layer and the second impurity diffusion layer.

8. A nonvolatile semiconductor device comprising a plurality of memory cell units arranged longitudinally and transversely in a matrix configuration, wherein the memory cell units each comprise a memory cell unit as recited in claim 6.

9. A nonvolatile semiconductor device of claim 8,
wherein a plurality of control gate lines are each provided by sequentially connecting control gates of memory cells provided in column-shaped semiconductor layers arranged longitudinally in each column of the matrix configuration, and are commonly connected,
wherein a plurality of bit lines are each provided by connecting drain diffusion layers provided in column-shaped semiconductor layers arranged transversely in each row of the matrix configuration.

10. A liquid crystal display device comprising a nonvolatile semiconductor device as recited in claim 8.
